(19) United States
(12) Patent Application Publication
(10) Pub. No.: US 2022/0244035 A1
(43) Pub. Date: Aug. 4, 2022

(54) Wavelength Sweeping Optical Measurement System

(71) Applicant: Nippon Telegraph and Telephone Corporation, Tokyo (JP)

(72) Inventors: Masahiro Ueno, Tokyo (JP); Yuichi Akage, Tokyo (JP); Soichi Oka, Tokyo (JP)

(21) Appl. No.: 17/626,711

(22) PCT Filed: Jul. 18, 2019
(86) PCT No.: PCT/JP2019/028300

§ 371 Date: Jan. 12, 2022

(51) Int. Cl. G01B 9/02091; G01J 9/02; G01B 9/02004

(52) U.S. Cl. CPC G01B 9/02091; G01B 9/02004; G01J 9/02

(57) ABSTRACT

A photoelectric conversion apparatus includes an interferometer configured to cause interference in wavelength swept light Lx output from a wavelength swept light source X and is configured to convert the interfered wavelength swept light by photoelectric conversion. A signal processing apparatus calculates, in chronological order, relative frequencies fr(t) indicating frequencies relative to interference signals i(t) obtained by the photoelectric conversion of the interference light iL, and measures a difference between a maximum value and a minimum value of the relative frequencies fr(t), as a sweep frequency width Δf of the wavelength swept light Lx.

### CROSS-REFERENCE TO RELATED APPLICATIONS

This application is a national phase entry of PCT Application No. PCT/JP2019/028300, filed on Jul. 18, 2019, which application is hereby incorporated herein by reference.

### TECHNICAL FIELD

The present invention relates to a wavelength swept light measurement technique for measuring a profile of a sweep frequency width and the like for a wavelength swept light source.

### BACKGROUND

Depth distance measurement methods including a frequency modulated continuous wave (FMCW) radar method, a swept source optical coherence tomography (SS-OCT) method, and an optical frequency domain reflectometry (OFDR) method use a wavelength swept light source, an interferometer, and a signal processing apparatus. A resolution of the depth distance in these methods is inversely proportional to a sweep frequency width of the wavelength swept light sources. Thus, in configuring a depth distance measurement apparatus using such methods, it is important to measure the sweep frequency width and a swept wavelength width to ensure the performance of the wavelength swept light source.

In measuring the sweep frequency width, an optical spectrum analyzer is typically employed to acquire a sweeping spectrum and obtain the sweep frequency width. NPLs 1 and 2 describe a dispersion spectroscopy and an interference spectroscopy of an optical spectrum analyzer.

In the dispersion spectroscopy, a dispersion element such as a prism or a diffraction grating, a slit, a photodetector, and a signal processing apparatus are used. When light to be measured enters the dispersion element, the light is divided (dispersed) according to an emission direction from the dispersion element and a location of the light depending on a wavelength of the light, and light of a certain wavelength is separated from the light dispersed by the slit, to obtain the intensity of the separated light of the certain wavelength by the photodetector. At this time, when the incident angle of the light to be measured on the dispersion element is changed by, for example, rotating the dispersion element, a wavelength passing the slit changes, and a wavelength-to-light intensity property (wavelength spectrum) is obtained by the signal processing apparatus, from a relationship between the incident angle and the wavelength passing the slit.

The interference spectroscopy includes two-beam interferometry using a Michelson interferometer, a Mach-Zehnder interferometer, or the like, and multi-beam interferometry using a Fabry-Perot interferometer.

In the two-beam interferometry, a two-beam interferometer, a photodetector, and a signal processing apparatus are used. In the interferometer, light to be measured is demultiplexed, and after each of the demultiplexed light beams passes through each of two optical paths, the demultiplexed light beams are multiplexed. A function of a multiplexed light intensity with optical path lengths of the two optical paths as variables is a sum of an autocorrelation function of the light to be measured and the intensities of each of the light beams. The multiplexed light intensity is acquired by the photodetector and subsequently Fourier-transformed by the signal processing apparatus, to obtain a power spectrum of the light to be measured.

In the multi-beam interferometry, a scanning Fabry-Perot interferometer is used. The scanning Fabry-Perot includes two high-reflective mirrors faced each other and being capable of continuously changing an interval between the high-reflective mirrors, a photodetector, and a signal processing apparatus are used.

Transmission spectral characteristics of the scanning Fabry-Perot interferometer have comb-teeth-shaped transmission characteristics in which light is passed at equal frequency intervals (with a free spectral range (FSR)). Each of the comb teeth is referred to as a vertical mode, and the frequency of each vertical mode is denoted by nFSR (n being an integer of 0 or greater). This n is referred to as a vertical mode order. The FSR varies in inverse proportion to the interval between the two high-reflective mirrors of the Fabry-Perot interferometer, and thus, this property is utilized by the optical spectrum analyzer.

When the frequency band of the light to be measured is smaller than the FSR, light passing only one order is passed from the Fabry-Perot interferometer. When the interval between the two high-reflective mirrors of the Fabry-Perot interferometer varies, the frequency of the order varies in inverse proportion to the variation. After the photodetector acquires the light intensity of the light passing the Fabry-Perot interferometer, the signal processing apparatus associates the light intensity and the frequency of the order to obtain a wavelength-to-light intensity property (wavelength spectrum). When only one Fabry-Perot interferometer is used in obtaining a spectrum having a wider band than in FSR, light passing a plurality of orders of vertical modes enters the photodetector. In order to avoid this, for example, it is necessary to use a device in which a plurality of Fabry-Perot interferometers are connected in series to limit the number of orders to one order.

### CITATION LIST

### Non Patent Literature

NPL 1: Akihisa Mikami, “Multimedia-Its Impact and Technology. Technologies and Applications of Speech Recognition and Speech Synthesis” Journal of the Society of Instrument and Control Engineers, Vol. 35, No. 1, pp. 29-32, published Jan. 10, 1996

NPL 2: Takao Tanimoto, “Various Measurement Technology in Laser Experiment—Principle of Optical Spectrum Analyzer and Notes in Measurement—”, The Review of Laser Engineering, Vol. 39, No. 5, pp. 354-361, published May 15, 2011.

### SUMMARY

### Technical Problem

The measurement apparatus described above acquires a temporally static optical spectrum, and is not suitable for a wavelength swept light source and the like that an optical spectrum varies over time, so that it is inherently difficult to accurately acquire a sweeping spectrum by the measurement apparatus. As a result, there is a problem in that the measurement apparatus cannot accurately measure a sweep frequency width of the wavelength swept light source.

Furthermore, when the sweeping speed of the wavelength swept light source is sufficiently fast with respect to a frequency sweeping speed of the optical spectrum analyzer in the dispersion spectroscopy, the swept wavelength width can be measured with a certain degree of accuracy. However, as the sweeping speed of the wavelength swept light source approaches the wavelength measurement speed of the optical spectrum analyzer, an unevenness occurs in the observed spectrum, and thus, there occurs a problem that it is not possible to accurately measure the sweep frequency width.

In order to clearly explain this problem, results of measuring a spectrum (wavelength spectrum) of a wavelength swept light source by using an optical spectrum analyzer employing the dispersion spectroscopy are illustrated in FIGS. 21 and 22. FIG. 21 is a graph showing a spectral measurement result (wavelength sweep frequency=10 Hz) of a wavelength swept light source. FIG. 22 is a graph showing a spectral measurement result (wavelength sweep frequency=100 Hz) of the wavelength swept light source.

As illustrated in FIGS. 21 and 22, the sweep frequency is employed instead of the sweeping speed of the light source, however, the sweep frequency and the sweeping speed are in a proportional relationship, and thus, as the sweeping speed increases, the sweeping speed is faster.

The wavelength swept light source employed in the spectral measurement has a configuration in which a current obtained by adding a direct current and an alternating current is applied to a distributed feedback (DFB) laser. The alternating waveform has a sine waveform, and a frequency of the sine waveform is a sweep frequency of the light source. During the measurement, the sweep frequency of the optical spectrum analyzer being used is about 1 Hz.

As illustrated in FIG. 21, in a spectral measurement result when the sweeping speed of the light source is slow (10 Hz), discrete values are observed for the wavelength, and thus, it is difficult to accurately read the swept wavelength (frequency) width of the light source. On the other hand, in the spectrum illustrated in FIG. 22 in which the sweeping speed of the light source is fast (100 kHz), continuous values are observed for the wavelength, and thus, it is possible to accurately read the swept wavelength (frequency) width. As described above, when the sweeping speed of the light source is slow, the observed spectrum is uneven and thus, the sweep frequency width cannot be accurately measured.

Note that the reason why the swept wavelength (sweep frequency) width is narrower at 100 kHz than at 10 Hz is due to the properties of a DFB laser. Furthermore, as seen in the results at 100 kHz, the light intensity level at both ends of the swept wavelength rises like a horn because the alternating waveform of the current applied to the DFB laser has a sine waveform, and thus, the time transition of the wavelength becomes slow toward the end of the swept wavelength, so that in the photodetector receiving the light inside the spectrum analyzer, the irradiation time per unit wavelength increases.

Embodiments of the present invention have been contrived to solve the above problem and an object thereof is to provide a wavelength swept light measurement technique capable of accurately measuring a profile such as a sweep frequency width for wavelength swept light, without being affected by a sweeping speed of a wavelength swept light source.

### Means for Solving the Problem

In order to achieve this object, a wavelength swept light measurement system according to embodiments of the present invention includes a photoelectric conversion apparatus including an interferometer configured to cause interference in wavelength swept light output from a wavelength swept light source, the photoelectric conversion apparatus being configured to convert the interfered wavelength swept light by photoelectric conversion, and a signal processing apparatus configured to calculate, in chronological order, relative frequencies indicating frequencies relative to interference signals obtained in the photoelectric conversion, and measure a difference between a maximum value and a minimum value of the relative frequencies as a sweep frequency width of the wavelength swept light.

Furthermore, another wavelength swept light measurement system according to embodiments of the present invention includes a photoelectric conversion apparatus including an interferometer configured to cause interference in wavelength swept light output from a wavelength swept light source, the photoelectric conversion apparatus being configured to convert, by photoelectric conversion, the interfered wavelength swept light and specific wavelength light detected by a narrow band wavelength filter from the wavelength swept light, and a signal processing apparatus configured to calculate, in chronological order, relative frequencies indicating frequencies relative to interference signals obtained by the photoelectric conversion of the interference light, calculate predicted frequencies indicating absolute frequencies for the relative frequencies, by referring to a detection timing of the specific wavelength light obtained by the photoelectric conversion of the specific wavelength light, and measure a difference between a maximum value and a minimum value of predicted wavelengths corresponding to the predicted frequencies, as a swept wavelength width of the wavelength swept light.

### Effects of Embodiments of the Invention

According to embodiments of the present invention, it is possible to measure a profile for wavelength swept light with extremely high precision and accuracy, without being affected by a sweeping speed of a wavelength swept light source.

### BRIEF DESCRIPTION OF THE DRAWINGS

FIG. 1 is a block diagram illustrating a configuration of a wavelength swept light measurement system according to a first embodiment.

FIG. 2 is a signal waveform chart for a signal extraction operation.

FIG. 3 is a signal waveform chart for a relative frequency calculation operation.

FIG. 4 is a block diagram illustrating an exemplary configuration of a relative frequency calculation unit according to the first embodiment.

FIG. 5 is a block diagram illustrating an exemplary configuration of a negative frequency component deletion unit according to the first embodiment.

FIG. 6 is a block diagram illustrating a configuration of a wavelength swept light measurement system according to a second embodiment.

FIG. 7 is a block diagram illustrating a configuration of a wavelength swept light measurement system according to a third embodiment.

FIG. 8 is a block diagram illustrating a configuration of a wavelength swept light measurement system according to a fourth embodiment.

FIG. 9 is a signal waveform chart for calculating a predicted frequency value.

FIG. 10 is a block diagram illustrating another exemplary configuration of a signal processing apparatus according to the fourth embodiment.

FIG. 11 is a block diagram illustrating another exemplary configuration of the signal processing apparatus according to the fourth embodiment.

FIG. 12 is a block diagram illustrating a configuration of a wavelength swept light measurement system according to a fifth embodiment.

FIG. 13 is a signal waveform chart for a sweep frequency width calculation operation.

FIG. 14 is a signal waveform chart showing a relationship between an optical spectrum and a resolution of depth information.

FIG. 15 is a block diagram illustrating a configuration of a wavelength swept light measurement system according to a sixth embodiment.

FIG. 16 is a block diagram illustrating a configuration of a wavelength swept light measurement system according to a seventh embodiment.

FIG. 17 is a block diagram illustrating a configuration of a wavelength swept light measurement system according to an eighth embodiment.

FIG. 18 is a block diagram illustrating an exemplary configuration of a relative frequency calculation unit according to the eighth embodiment.

FIG. 19 is a block diagram illustrating a configuration of a wavelength swept light measurement system according to a ninth embodiment.

FIG. 20 is a block diagram illustrating a configuration of a wavelength swept light measurement system according to a tenth embodiment.

FIG. 21 is a graph showing a spectral measurement result (wavelength sweep frequency=10 Hz) of a wavelength swept light source.

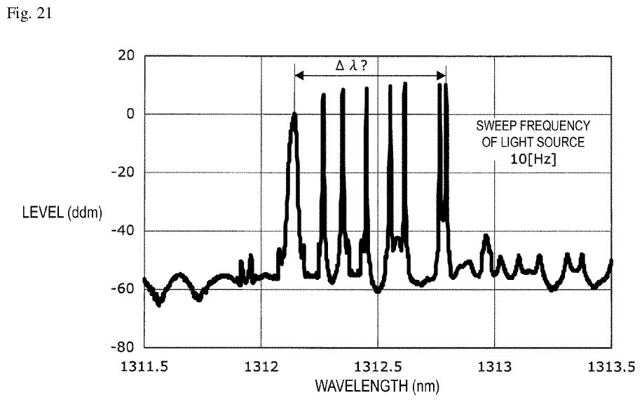

FIG. 22 is a graph showing a spectral measurement result (wavelength sweep frequency=100 kHz) of a wavelength swept light source.

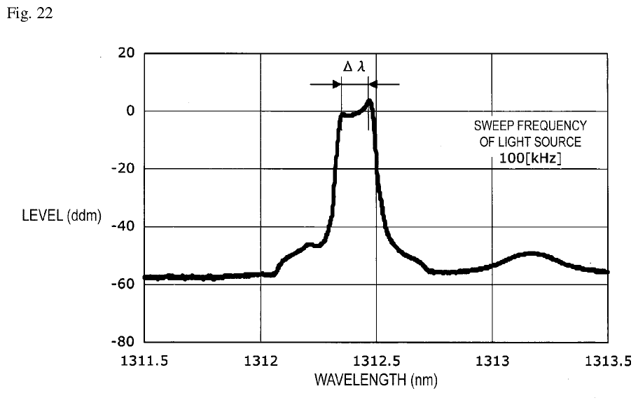

### DETAILED DESCRIPTION OF ILLUSTRATIVE EMBODIMENTS

Embodiments of the present invention will be described below with reference to the drawings.

### First Embodiment

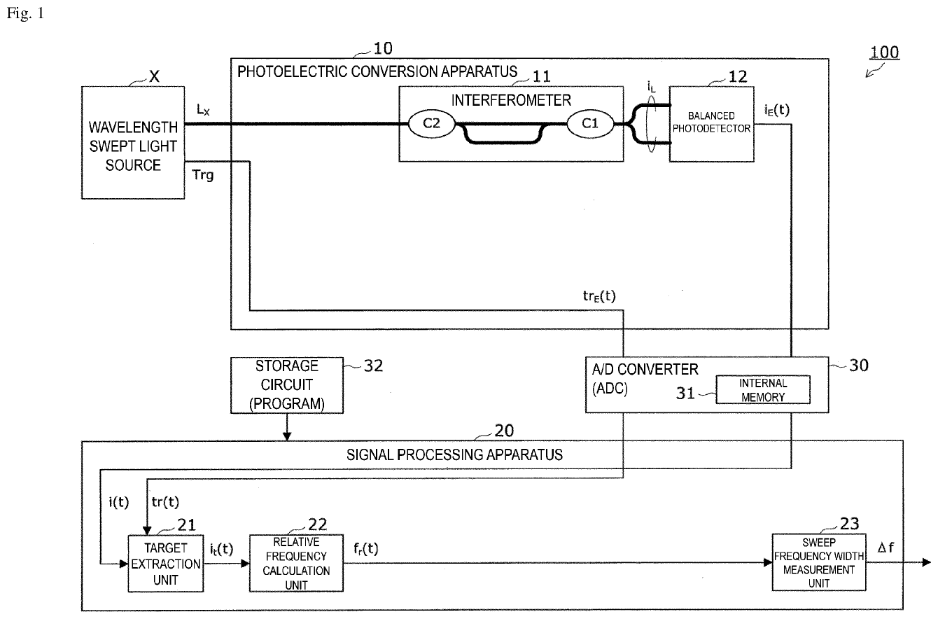

First, a wavelength swept light measurement system 100 according to a first embodiment of the present invention will be described with reference to FIG. 1. FIG. 1 is a block diagram illustrating a configuration of a wavelength swept light measurement system according to the first embodiment.

The wavelength swept light measurement system 100 according to embodiments of the present invention is a system for measuring a profile such as a swept wavelength width Δλ for a wavelength swept light source X, on the basis of wavelength swept light Lx, to be measured, output from the wavelength swept light source X.

The wavelength swept light source X is a laser light source capable of sweeping a wavelength of oscillating light at high speed and in a wide range. In the wavelength swept light source X, a time-optical frequency pattern is the same for every sweep operation, and a trigger electrical signal Trg is output in synchronization with the sweep operation.

As illustrated in FIG. 1, the wavelength swept light measurement system 100 according to embodiments of the present invention includes, as main components, a photoelectric conversion apparatus 10, a signal processing apparatus 20, and an A/D converter (ADC) 30.

### Photoelectric Conversion Apparatus

The photoelectric conversion apparatus 10 includes an interferometer ii that generates interference light iL by causing an interference in the wavelength swept light Lx, to be measured, output from the wavelength swept light source X, and a balanced photodetector 12 that outputs an interference electrical signal i_{E}(t) by photoelectrically converting the obtained interference light iL.

The interferometer 11 illustrated in FIG. 1 is a Mach-Zehnder type interferometer. The interferometer 11 has a structure in which two fibers having different optical path lengths are connected between a coupler C2 and a coupler C1, and light branched by the coupler C2 passes through each of the optical paths and is combined by the C1.

The balanced photodetector 12 is a typical differential amplification-type photodetector and differentially amplifies and photoelectrically converts the two light beams of the interference light iL branched by the C1, to output the interference electrical signal i_{E}(t).

The interferometer 11 is not limited to the Mach-Zehnder type interferometer, and may be a Michelson-type or a Fabry-Perot interferometer. In the case of the Fabry-Perot type interferometer, a normal photodetector may be used instead of the balanced photodetector 12. Furthermore, in FIG. 1, an exemplary configuration in which an optical fiber is used for the interferometer 11 is explained, however, when wavelength dispersion in the optical fiber poses a problem, a spatial optical system may be used.

### A/D Converter

The A/D converter (ADC) 30 is a typical A/D converter having a trigger function. The ADC 30 A/D-converts a trigger electrical signal tr_{E}(t) that is the trigger electrical signal Trg of the wavelength swept light source X and input from the photoelectric conversion apparatus 10, at each time t, and outputs, in chronological order, trigger signals tr(t) composed of digital data. Furthermore, the ADC 30 A/D-converts the interference electrical signal i_{E}(t) input from the photoelectric conversion apparatus 10, at each time t, and outputs, in chronological order, interference signals i(t) composed of digital data.

At this time, the ADC 30 includes therein a memory 31 and saves, in the memory 31 in chronological order, the interference signals i(t) during an effective period Tₘₑₘ having a duration of one or more sweeps from a sweep start specified by the trigger electrical signal tr_{E}(t), and in response to a request from the signal processing apparatus 20, reads and outputs the interference signals i(t) for a specified period of the effective period Tₘₑₘ from the memory 31. The memory 31 may be an external memory externally connected to the ADC 30.

### Signal Processing Apparatus

The signal processing apparatus 20 includes a microprocessor such as a digital service unit (DSU) and a CPU. The signal processing apparatus 20 realizes, when the microprocessor and a program stored in a storage apparatus 32 are jointly operated, various types of signal processes for calculating a profile for the wavelength swept light Lx of the wavelength swept light source X, that is, in this case, a sweep frequency width Δf.

As illustrated in FIG. 1, the signal processing apparatus 20 realizes, as main processing units, a target extraction unit 21, a relative frequency calculation unit 22, and a sweep frequency width measurement unit 23. Note that each of the processing units of the signal processing apparatus 20 may be realized by dedicated hardware, that is, a signal processing circuit.

### Target Extraction Unit

The target extraction unit 21 of the signal processing apparatus 20 illustrated in FIG. 1 will be described. A sweep interval T_{aq} represents a period during which the wavelength swept light Lx is swept from a maximum frequency to a minimum frequency. The target extraction unit 21 is configured to extract an interference signal i(t) in the sweep interval T_{aq} as a signal processing target and output the extracted interference signal i(t) as a target interference signal it(t). Hereinafter, the target interference signal it(t) may be simply referred to as an interference signal i(t), and the interference signal i(t) may be referred to as an interference signal intensity i(t).

Specifically, first, the target extraction unit 21 detects an output timing at which the trigger electrical signal Trg is output from the wavelength swept light source X, on the basis of an intensity of the trigger signal tr(t) from the ADC 30. Subsequently, the target extraction unit 21 identifies, each time the output timing is detected, the sweep interval T_{aq} by referring to a trigger time T_{trg} indicating the output timing, and extracts, from the ADC 30, the target interference signal iₜ(t) corresponding to the sweep interval T_{aq}.

Thus, it is only required in the ADC 30 that the interference signal i(t) is sequentially updated and held in the memory 31 of the ADC 30 for the predetermined effective period Tₘₑₘ, for example. Consequently, when the target extraction unit 21 reads the interference signal i(t) from the memory 31 of the ADC 30 during an interval from the maximum frequency to the minimum frequency of the wavelength swept light Lx, that is, during the sweep interval T_{aq}, the target extraction unit 21 can extract the target interference signal iₜ(t).

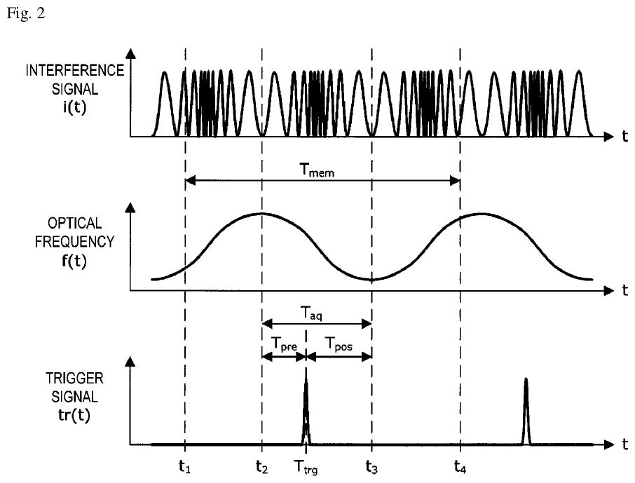

A signal extraction operation in the target extraction unit 21 will be described with reference to FIG. 2. FIG. 2 is a signal waveform chart for a signal extraction operation. FIG. 2 illustrates waveforms each indicating temporal changes in the intensity of the interference signal i(t), an optical frequency f(t) of the wavelength swept light Lx, and the intensity of the trigger signal tr(t). Hereinafter, curves indicating a relative frequency fᵣ(t) and a frequency f(t) relative to a time t may be referred to as a relative frequency change curve fᵣ(t) and a frequency change curve f(t).

In FIG. 2, an interval from a time t1 to a time t4 indicates the effective period Tₘₑₘ, and an interval from a time t2 to a time t3 in the effective period Tₘₑₘ indicates the sweep interval T_{aq}. The sweep interval T_{aq} is identified by referring to the trigger time T_{trg} being a peak of the trigger signal tr(t). Specifically, a time point earlier than the trigger time T_{trg} by a pre-time Tₚᵣₑ is a start time of the sweep interval T_{aq}, that is, the time t2. Furthermore, a time point later than the trigger time T_{trg} by a post-time Tₚₒₛ is an end time of the sweep interval T_{aq}, that is, the time t3. The pre-time Tₚᵣₑ and the post-time Tₚₒₛ are previously set.

The effective period Tₘₑₘ has a duration longer than a wavenumber period of the wavelength swept light Lx, and thus, even when the trigger time T_{trg} shifts before and behind to some extent, it is possible to stably extract the target interference signal iₜ(t) during the sweep interval T_{aq} from the interference signal i(t).

FIG. 2 illustrates an example in which a signal is extracted in the sweep interval T_{aq} being an interval from a minimum frequency to a maximum frequency. However, the same applies to a case where a signal is extracted in an interval from a maximum frequency to a minimum frequency.

### Relative Frequency Calculation Unit

The relative frequency calculation unit 22 of the signal processing apparatus 20 illustrated in FIG. 1 will be described.

On the basis of the target interference signal iₜ(t) for the sweep interval T_{aq} extracted by the target extraction unit 21, the relative frequency calculation unit 22 is configured to calculate a difference at each time t between a reference frequency f(t2) at a reference time and a frequency f(t) of the target interference signal iₜ(t) at each time, where the reference time is an initial time of the sweep interval T_{aq}, that is, the time t2 at which the maximum frequency is output in FIG. 2, instead of using an absolute frequency of the light, and to output the obtained difference as the relative frequency fᵣ(t).

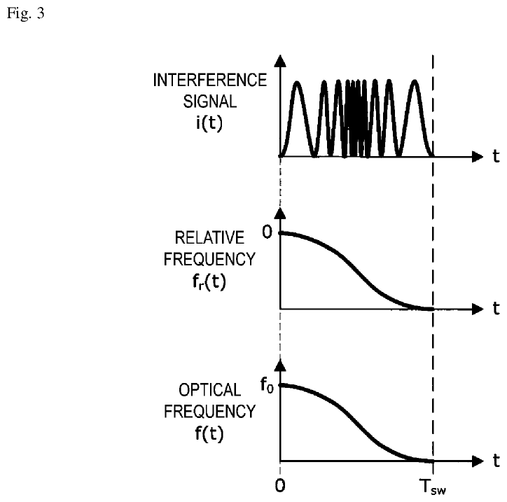

A relative frequency calculation operation by the relative frequency calculation unit 22 will be described with reference to FIG. 3. FIG. 3 is a signal waveform chart for the relative frequency calculation operation. FIG. 3 illustrates waveforms each indicating temporal changes in the intensity of the interference signal i(t), the relative frequency fᵣ(t) of the wavelength swept light Lx, and the optical frequency f(t) of the wavelength swept light Lx.

In FIG. 3, an earliest time of the sweep interval T_{aq} in FIG. 2, that is, a start time t is replaced by 0, and an end time t of the sweep interval T_{aq} is replaced by an end time T_{sw}. The relative frequency fᵣ(t) is expressed by Equation (1) below where the relative frequency fᵣ(0) is a reference (fᵣ(0)=0).

Math. 1

fᵣ(t)=f(t)−f(0)=f(t)−f₀ (1)

where f₀ is actually a value of the frequency f(0) of light output from a light source at a time t=0.

The relative frequency calculation unit 22 determines the relative frequency fᵣ(t) from the phase of the target interference signal iₜ(t). This is on the basis of the following principle.

According to reference literature (Yoshiaki Yasuno, Violeta Dimitrova Madjarova, Shuichi Makita, Masahiro Akiba, Atsushi Morosawa, Changho Chong, Toni Sakai, Kin-Pui Chan, Masahide Itoh, and Toyohiko Yatagai, “Three-dimensional and high-speed swept-source optical coherence tomography for in vivo investigation of human anterior eyesegments”, OPTICS EXPRESS, Vol. 13, No. 26, pp. 10652-10664, 2005), the interference signal i(t) is expressed by Equation (2) below.

$$\begin{matrix}Math . 2 & \\ i ( t ) = a ( t ) cos ( \frac{4 π z}{c} f ( t ) ) & ( 2 )\end{matrix}$$

where z is a difference of the optical path lengths in the interferometer.

In Equation (2), a(t) is an amplitude and is, according to the reference literature, proportional to the photon efficiency of the photodetector, the coherence function of the light of the light source, and the magnitude of the electric field of the two optical paths in the interferometer. Furthermore, c is a speed of light. When the amplitude a(t) is constant, a phase θ(t) of the interference signal i(t) is expressed by Equation (3) below. Consequently, if the phase θ(t) is determined, a frequency f(x) can be obtained by Equation (4) below.

$$\begin{matrix}Math . 3 & \\ θ ( t ) = \frac{4 π z}{c} f ( t ) & ( 3 ) \\ Math . 4 & \\ f ( t ) = \frac{c}{4 π z} θ ( t ) & ( 4 )\end{matrix}$$

Incidentally, the interference signal i(t) may be deformed as in Equation (5) below, and when the amplitude a(t) is substantially a constant value a₀, the interference signal i(t) is given by Equation (6) below.

$$\begin{matrix}Math . 5 & \\ i ( t ) = \frac{a ( t )}{2} ( {e}^{j \frac{4 π z}{c} f ( t )} + {e}^{- j \frac{4 π z}{c} f ( t )} ) & ( 5 ) \\ Math . 6 & \\ i ( t ) ≅ \frac{{a}_{0}}{2} ( {e}^{j \frac{4 π z}{c} f ( t )} + {e}^{- j \frac{4 π z}{c} f ( t )} ) & ( 6 )\end{matrix}$$

where j is in units of imaginary numbers.

The interference signal i(t) can be expressed by Equation (7) below. If the exponential part of the Napiar number e in Equation (7) is compared with that in Equation (6), the instantaneous frequency fᵢ(t) of the interference signal i(t) is expressed by Equation (8) below.

$$\begin{matrix}Math . 7 & \\ i ( t ) ≅ \frac{{a}_{0}}{2} ( {e}^{j 2 π {f}_{i} ( t ) t} + {e}^{- j 2 π {f}_{i} ( t ) t} ) & ( 7 )\end{matrix}$$

where fᵢ(t) is an instantaneous frequency of the interference signal i(t) at a time t.

$$\begin{matrix}Math . 8 & \\ {{f}_{i} ( t ) = \frac{z}{c} \frac{d f}{d t} \vert}_{t} & ( 8 )\end{matrix}$$

Thus, it can be understood that the interference signal i(t) is a signal having a frequency of ±(z/c) df/dt|ₜ. A signal i′(t) that is a signal obtained by deleting a negative frequency component from the interference signal i(t)is expressed by Equation (9) below.

$$\begin{matrix}Math . 9 & \\ {i}^{′} ( t ) ≅ \frac{{a}_{0}}{2} {e}^{j \frac{4 π z}{c} f ( t )} = \frac{{a}_{0}}{2} ( cos ( \frac{4 π z}{c} f ( t ) ) + j sin ( \frac{4 π z}{c} f ( t ) ) ) & ( 9 )\end{matrix}$$

As in Equation (9), the signal i′(t) is a complex number, and thus, the phase θ(t)=(4πz/c) f(t) is determined as an argument of the signal i′(t). The phase θ(t) is expressed by Equation (10) below.

Math. 10

θ(t)=arg(i′(t)) (10)

where arg(.) is a function for determining the argument from a complex number.

It should be noted that an argument obtained from the actual signal i′(t) can only be obtained from a principal value (value in a range from 0 to 2π). That is, the argument obtained from the actual signal i′(t) is not the original value, but a value wrapped in the range from 0 to 2π is obtained. Here, an original argument θ(t) is expressed by Equation (11) below.

Math. 11

θ(t)=θᵣ(t)+θ₀=unwrap(Arg(i′(t)))+θ₀ (11)

where θ(0)=θ₀ is the original argument at time t=0, Arg(.) is a function for obtaining the principal value of the argument from a complex number, and unwrap(.) is a function for unwrapping a value.

Note that, an argument not including θ₀ is referred to as a relative phase θr(t) so as to distinguish from the original phase.

Consequently, from Equations (4) and (11), the frequency f(x) of the wavelength swept light Lx is expressed by Equation (12) below.

$$\begin{matrix} Math . 12 & \\ f ( t ) = \frac{c}{4 π z} θ ( t ) = \frac{c}{4 π z} ( {θ}_{r} ( t ) + {θ}_{0} ) = \frac{c}{4 π z} ( unwrap ( Arg ( {i}^{′} ( t ) ) ) + {θ}_{0} ) = \frac{c}{4 π z} unwrap ( Arg ( {i}^{′} ( t ) ) ) + \frac{c}{4 π z} {θ}_{0} & ( 12 )\end{matrix}$$

In comparison between Equation (1) and Equation (12), it can be understood that the relative frequency fᵣ(t) and the frequency f₀ (=f(0)) of the light output from the light source at time t=0 correspond to each other as in Equations (13) below.

$$\begin{matrix}Math . 13 & \\ {f}_{r} ( t ) = \frac{c}{4 π z} unwrap ( Arg ( {i}^{′} ( t ) ) ) \\ {f}_{0} = \frac{c}{4 π z} {θ}_{0} = \frac{c}{4 π z} θ ( 0 ) & ( 13 )\end{matrix}$$

Thus, it can be understood that the principal value of the argument of the signal i′(t) obtained by removing the negative frequency component from the interference signal i(t) is determined, and the argument is multiplied by c/4πz to obtain the relative frequency fᵣ(t) of the wavelength swept light Lx.

### Exemplary Configuration of Relative Frequency Calculation Unit

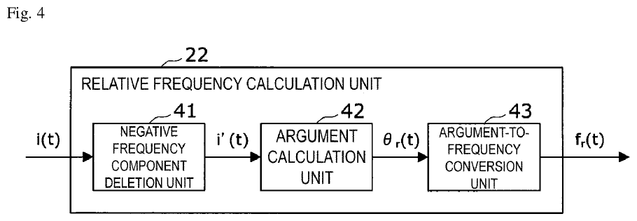

An exemplary configuration of the relative frequency calculation unit 22 in the signal processing apparatus 20 in FIG. 1 will be described in detail with reference to FIG. 4. FIG. 4 is a block diagram illustrating an exemplary configuration of a relative frequency calculation unit according to the first embodiment. As illustrated in FIG. 4, the relative frequency calculation unit 22 includes a negative frequency component deletion unit 41, an argument calculation unit 42, and an argument-to-frequency conversion unit 43, as main processing units.

In the relative frequency calculation unit 22, the negative frequency component deletion unit 41 deletes a negative frequency component from the input interference signal i(t) and outputs the signal i′(t). The argument calculation unit 42 determines and outputs a relative argument θr(t) of the signal i′(t) output from the negative frequency component deletion unit 41. The argument-to-frequency conversion unit 43 determines and outputs the relative frequency fᵣ(t) of the wavelength swept light Lx, on the basis of the relative argument θr(t) output from the argument calculation unit 42.

### Exemplary Configuration of Negative Frequency Component Deletion Unit

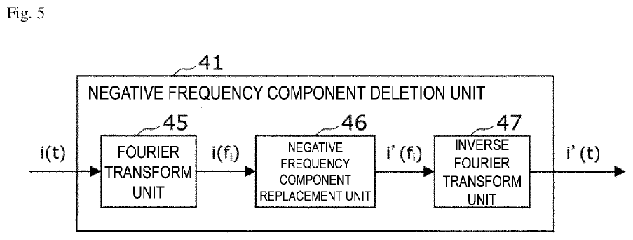

An exemplary configuration of the negative frequency component deletion unit 41 in the relative frequency calculation unit 22 in FIG. 4 will be described in detail with reference to FIG. 5. FIG. 5 is a block diagram illustrating an exemplary configuration of a negative frequency component deletion unit according to the first embodiment. As illustrated in FIG. 5, the negative frequency component deletion unit 41 includes a Fourier transform unit 45, a negative frequency component replacement unit 46, and an inverse Fourier transform unit 47, as main processing units.

In the negative frequency component deletion unit 41, the Fourier transform unit 45 transforms the input interference signal i(t) by Fourier transform (frequency transformation), and outputs a signal i(fᵢ) resulting from the Fourier transform. The negative frequency component replacement unit 46 replaces a negative frequency component of the signal i(fᵢ) output from the Fourier transform unit 45 with zero, and outputs a signal i′(fᵢ) resulting from the replacement. The inverse Fourier transform unit 47 transforms the signal i′(fᵢ) output from the negative frequency component replacement unit 46 by inverse Fourier transform, and outputs a signal i′(t) resulting from the inverse Fourier transform.

### Sweep Frequency Width Measurement Unit

The sweep frequency width measurement unit 23 of the signal processing apparatus 20 illustrated in FIG. 1 will be described. The sweep frequency width measurement unit 23 is configured to measure and output the sweep frequency width Δf of the wavelength swept light Lx, on the basis of the relative frequency fᵣ(t) of the wavelength swept light Lx output from the relative frequency calculation unit 22. When the relative frequency fᵣ(t) of the wavelength swept light Lx is a curve as illustrated in FIG. 3 described above, a difference between a maximum value and a minimum value of the relative frequency fᵣ(t) is measured and output as the sweep frequency width Δf.

### Effect of First Embodiment

As described above, in the present embodiment, the photoelectric conversion apparatus 10 photoelectrically converts the interference light iL obtained as a result of interference of the wavelength swept light Lx output from the wavelength swept light source X in the interferometer 11, and outputs the photoelectrically converted interference light iL. The signal processing apparatus 20 calculates, in chronological order, relative frequencies fᵣ(t) indicating frequencies relative to the interference signals i(t) obtained by the photoelectric conversion of the interference light iL, and measures a difference between a maximum value and a minimum value of the relative frequencies fᵣ(t), as the sweep frequency width Δf of the wavelength swept light Lx.

Consequently, unlike a case where the sweep frequency width of a wavelength swept light source is measured on the basis of an optical spectrum acquired by dispersion spectroscopy, it is possible to measure the sweep frequency width Δf of the wavelength swept light Lx with extremely high precision and accuracy, regardless of a sweeping speed of the wavelength swept light source X.

Furthermore, in the present embodiment, in the signal processing apparatus 20, the target extraction unit 21 may extract, from the interference signals i(t), a target interference signal iₜ(t) corresponding to the sweep interval T_{aq} in which the wavelength swept light Lx is swept from a maximum frequency to a minimum frequency, the relative frequency calculation unit 22 may calculate a difference between the frequency of the extracted target interference signal iₜ(t) at a reference time and the frequency of the target interference signal iₜ(t) at each time, as the relative frequencies fₜ(t), and the sweep frequency width measurement unit 23 may measure a difference between a maximum value and a minimum value of the obtained relative frequencies fᵣ(t), as the sweep frequency width Δf of the wavelength swept light Lx. Consequently, the sweep frequency width Δf of the wavelength swept light Lx can be measured with a relatively simple process.

Furthermore, there is further provided the ADC 30 that A/D-converts the interference electrical signal i_{E}(t) output from the photoelectric conversion apparatus 10 into an interference signal i(t) composed of digital data in the present embodiment, and the ADC 30 is required to A/D-convert the interference electrical signal i_{E}(t) at each time t during the effective period Tₘₑₘ having a duration of one or more sweeps from a start of sweeping of the wavelength swept light Lx, save the obtained interference signal i(t) into the memory 31 in chronological order, and, in response to a request from the signal processing apparatus 20, read the interference signal i(t) for a specified period of the effective period Tₘₑₘ from the memory 31, to output the read interference signal i(t). Consequently, the interference signals i(t) required for measuring the sweep frequency width Δf can be easily provided to the signal processing apparatus 20.

### Second Embodiment

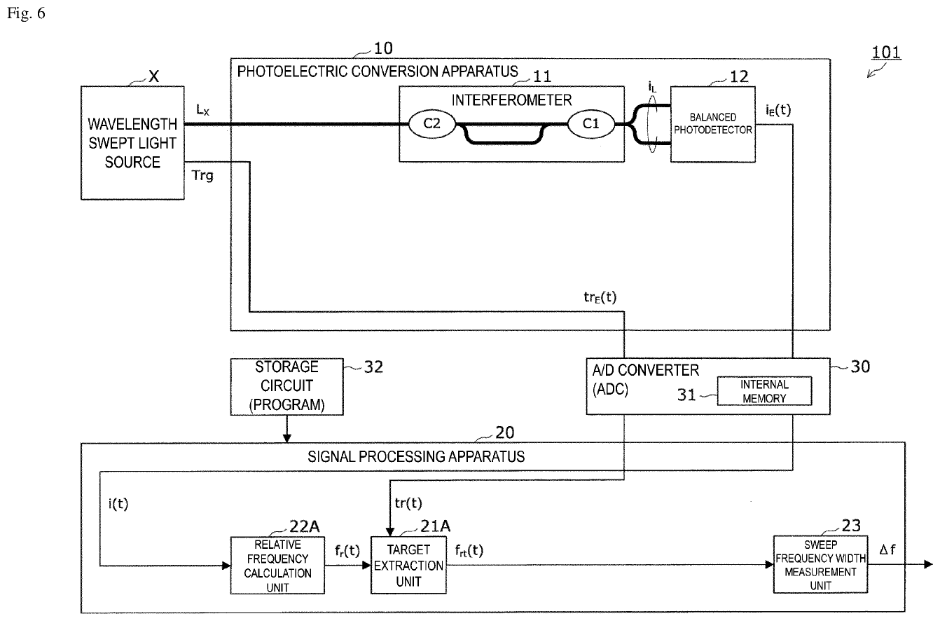

Next, a wavelength swept light measurement system 101 according to a second embodiment of the present invention will be described with reference to FIG. 6. FIG. 6 is a block diagram illustrating a configuration of a wavelength swept light measurement system according to the second embodiment.

As illustrated in FIG. 6, the wavelength swept light measurement system 101 according to the present embodiment and the wavelength swept light measurement system 100 according to the first embodiment illustrated in FIG. 1 are different in that an arrangement relationship between the target extraction unit 21 and the relative frequency calculation unit 22 is interchanged in the signal processing apparatus 20. Consequently, processing contents in the target extraction unit 21 and the relative frequency calculation unit 22 are different from those in the first embodiment, and thus, in the present embodiment, the target extraction unit 21 and the relative frequency calculation unit 22 are referred to as a target extraction unit 21A and a relative frequency calculation unit 22A, respectively.

Note that the sweep frequency width measurement unit 23 of the signal processing apparatus 20 is similar to that in FIG. 1. Furthermore, the photoelectric conversion apparatus 10, the ADC 30, and the storage apparatus 32 in the wavelength swept light measurement system 101 according to the present embodiment are similar to those in the first embodiment, and thus, detailed description thereof will be omitted here.

### Signal Processing Apparatus

The signal processing apparatus 20 includes a microprocessor such as a digital service unit (DSU) and a CPU, and realizes, when the microprocessor and a program stored in the storage apparatus 32 are jointly operated, various types of signal processes for calculating a profile for the wavelength swept light Lx of the wavelength swept light source X, that is, in this case, a sweep frequency width Δf.

As illustrated in FIG. 6, the signal processing apparatus 20 realizes the relative frequency calculation unit 22A, the target extraction unit 21A, and the sweep frequency width measurement unit 23, as main processing units. Note that each of the processing units of the signal processing apparatus 20 may be realized by dedicated hardware, that is, a signal processing circuit.

### Relative Frequency Calculation Unit

The relative frequency calculation unit 22A of the signal processing apparatus 20 illustrated in FIG. 6 will be described. The relative frequency calculation unit 22A is configured to calculate, on the basis of all interference signals i(t) for the effective period Tₘₑₘ saved in the ADC 30, a difference frequency at each time t between a reference frequency f(t) at a reference time, instead of using an absolute frequency of the light, and the frequency f(t) of the interference signal i(t) at each time, where the reference time is an initial time of the effective period Tₘₑₘ, that is, a time at which the maximum frequency is output in FIG. 2, and to output the obtained difference frequency as the relative frequency fᵣ(t). A technique for calculating the relative frequency fᵣ(t) is similar to that in the first embodiment.

### Target Extraction Unit

The target extraction unit 21A of the signal processing apparatus 20 illustrated in FIG. 6 will be described. The target extraction unit 21A is configured to calculate a time differential value dfᵣ(t)/dt of a relative frequency change curve obtained from the relative frequency fᵣ(t) output from the relative frequency calculation unit 22A, to extract and output the relative frequency fᵣ(t) corresponding to the sweep interval T_{aq} identified from the time differential value dfᵣ(t)/dt.

As illustrated in FIG. 2, a time when the time differential value satisfies dfᵣ(t)/dt=0 is at a position where the frequency of the wavelength swept light Lx has a maximum value or a minimum value, and thus, the relative frequency fᵣ(t) including the maximum value and the minimum value can be obtained by extracting the relative frequency fᵣ(t) at these positions. Consequently, it is required to identify, in the time when the time differential value satisfies dfᵣ(t)/dt=0, a period between a time closest and a time second-closest to the trigger time T_{trg} of the trigger signal tᵣ(t), as the sweep interval T_{aq}, and to extract and output the relative frequency fᵣ(t) corresponding to the sweep interval T_{aq}.

### Sweep Frequency Width Measurement Unit

The sweep frequency width measurement unit 23 of the signal processing apparatus 20 illustrated in FIG. 6 will be described. As in FIG. 1, the sweep frequency width measurement unit 23 is configured to measure and output the sweep frequency width Δf of the wavelength swept light Lx, on the basis of the relative frequency fᵣ(t) of the wavelength swept light Lx output from the relative frequency calculation unit 22A. When the relative frequency fᵣ(t) of the wavelength swept light Lx is a curve as illustrated in FIG. 3 described above, a difference between a maximum value and a minimum value of the relative frequency fᵣ(t) is measured and output as the sweep frequency width Δf.

### Effect of Second Embodiment

As described above, in the present embodiment, in the signal processing apparatus 20, the relative frequency calculation unit 22A calculates a difference between a frequency of the interference signals i(t) at a reference time and a frequency of the interference signals i(t) at each time, as the relative frequencies fᵣ(t), the target extraction unit 21A extracts, from the relative frequencies fᵣ(t), target relative frequencies fᵣₜ(t) corresponding to the sweep interval T_{aq} in which the wavelength swept light Lx is swept from a maximum frequency to a minimum frequency, and the sweep frequency width measurement unit 23 measures a difference between a maximum value and a minimum value of the obtained target relative frequencies fᵣₜ(t), as the sweep frequency width Δf of the wavelength swept light Lx. Thus, unlike the first embodiment, the sweep interval T_{aq} can be automatically identified.

### Third Embodiment

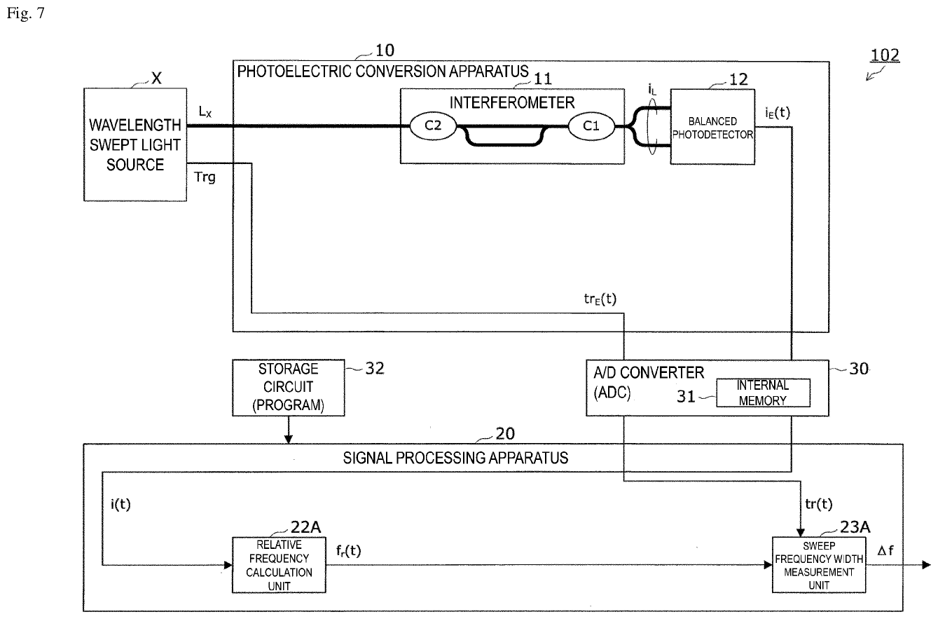

Next, a wavelength swept light measurement system 102 according to a third embodiment of the present invention will be described with reference to FIG. 7. FIG. 7 is a block diagram illustrating a configuration of a wavelength swept light measurement system according to the third embodiment.

As illustrated in FIG. 7, the wavelength swept light measurement system 102 according to the present embodiment is different from the wavelength swept light measurement system 101 according to the second embodiment illustrated in FIG. 6 in that the sweep frequency width measurement unit 23 has a function of the target extraction unit 21A in the signal processing apparatus 20. Thus, in the present embodiment, a processing unit having the functions of signal extraction and sweep frequency width measurement is described as a sweep frequency width measurement unit 23A.

Note that the relative frequency calculation unit 22A of the signal processing apparatus 20 is similar to that in FIG. 6. Furthermore, the photoelectric conversion apparatus 10, the ADC 30, and the storage apparatus 32 in the wavelength swept light measurement system 102 according to the present embodiment are similar to those in FIG. 1, and thus, detailed description thereof will be omitted here.

### Signal Processing Apparatus

The signal processing apparatus 20 includes a microprocessor such as a digital service unit (DSU) and a CPU, and realizes, when the microprocessor and a program stored in the storage apparatus 32 are jointly operated, various types of signal processing units for calculating a profile for the wavelength swept light Lx of the wavelength swept light source X, that is, in this case, a sweep frequency width Δf.

As illustrated in FIG. 7, the signal processing apparatus 20 realizes the relative frequency calculation unit 22A and the sweep frequency width measurement unit 23A, as main processing units. Note that each of the processing units of the signal processing apparatus 20 may be realized by dedicated hardware, that is, a signal processing circuit.

### Relative Frequency Calculation Unit

The relative frequency calculation unit 22A of the signal processing apparatus 20 illustrated in FIG. 7 will be described. As in FIG. 6, the relative frequency calculation unit 22A is configured to calculate, on the basis of all interference signals i(t) for the effective period Tₘₑₘ saved in the ADC 30, a difference frequency at each time t between a reference frequency f(t) at a reference time, instead of using an absolute frequency of the light, and the frequency f(t) of the interference signal i(t) at each time, where the reference time is an initial time of the effective period Tₘₑₘ, that is, a time at which the maximum frequency is output in FIG. 2, and to output the obtained difference frequency as the relative frequency fr(t). A technique for calculating the relative frequency fᵣ(t) is similar to that in the first embodiment.

### Sweep Frequency Width Measurement Unit

The sweep frequency width measurement unit 23A is configured to first calculate the time differential value dfᵣ(t)/dt of the relative frequency change curve obtained from the relative frequency fr(t), and to measure and output a difference between a maximum value and a minimum value of the relative frequency fᵣ(t) identified from the time differential values dfᵣ(t)/dt, as the sweep frequency width Δf.

As illustrated in FIG. 2, a time when the time differential value satisfies dfᵣ(t)/dt=0 is at a position where the frequency of the wavelength swept light Lx has a maximum value or a minimum value, and thus, the maximum value and the minimum value of the relative frequency fᵣ(t) can be obtained by extracting the relative frequency fᵣ(t) at these positions. Consequently, it is only required to identify, in the time when the time differential value satisfies dfᵣ(t)/dt=0, a time closest and a time second-closest to the trigger time Ttrg of the trigger signal tᵣ(t), and to measure a difference between the relative frequencies fᵣ(t) at these two times, as the sweep frequency width Δf.

### Effect of Third Embodiment

As described above, in the present embodiment, in the signal processing apparatus 20, the relative frequency calculation unit 22 calculates a difference between the frequency of the interference signals i(t) at the reference time and the frequency of the interference signals i(t) at each time, as the relative frequencies fᵣ(t), and the sweep frequency width measurement unit 23A calculates time differential values dfᵣ(t)/dt of the relative frequency change curve obtained from the relative frequencies fᵣ(t), and measures a difference between a maximum value and a minimum value of the relative frequencies fᵣ(t) identified from the time differential values dfᵣ(t)/dt, as the sweep frequency width Δf. Consequently, it is possible to omit a process of obtaining the maximum value and the minimum value from the relative frequency fᵣ(t), and thus, unlike the second embodiment, a processing amount can be reduced in the signal processing apparatus 20.

### Fourth Embodiment

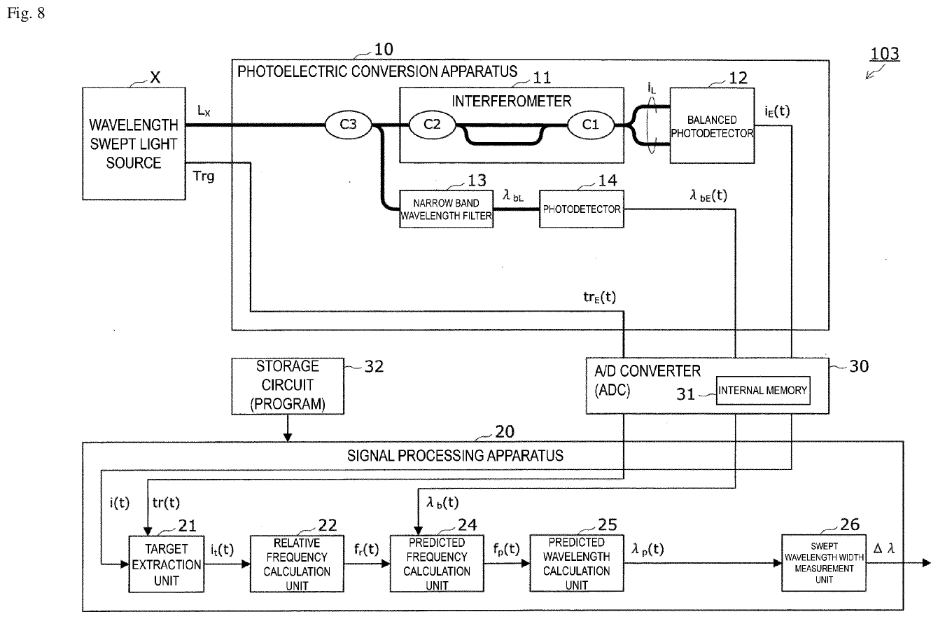

Next, a wavelength swept light measurement system 103 according to a fourth embodiment of the present invention will be described with reference to FIG. 8. FIG. 8 is a block diagram illustrating a configuration of a wavelength swept light measurement system according to the fourth embodiment.

As illustrated in FIG. 8, the wavelength swept light measurement system 103 according to the present embodiment is different from the wavelength swept light measurement system 100 according to the first embodiment illustrated in FIG. 1 in that the photoelectric conversion apparatus 10 includes a narrow band wavelength filter, so that a detection timing at which a specific wavelength light λ_{bL} having a specific wavelength, that is, a previously set wavelength λ_{base} is detected in the wavelength swept light Lx, is identified, and a swept wavelength width Δλ of the wavelength swept light Lx is measured on the basis of an absolute predicted frequency value fₚ(t) obtained from the relative frequency fᵣ(t) at the detection timing.

### Photoelectric Conversion Apparatus

In addition to the interferometer 11 and the balanced photodetector 12 as with those illustrated in FIG. 1, the photoelectric conversion apparatus 10 includes a narrow band wavelength filter 13 that detects the specific wavelength light λ_{bL} from the wavelength swept light Lx, and a photodetector 14 that photoelectrically converts the specific wavelength light λ_{bL} detected by the narrow band wavelength filter 13.

In the first embodiment, the wavelength swept light Lx is directly input to the interferometer 11, but in the present embodiment, the wavelength swept light Lx is branched into two light beams by using a coupler C3, and the two light beams are simultaneously input to each of the interferometer 11 and the narrow band wavelength filter 13.

The specific wavelength light λ_{bL} detected by the narrow band wavelength filter 13 is photoelectrically converted by the photodetector 14 into a specific wavelength electrical signal λ_{bE}(t) and then input to the ADC 30.

The narrow band wavelength filter 13 passes light centered on the previously set wavelength λ_{base} among the wavelength swept light Lx. Note that the wavelength λ_{base} is within a swept wavelength band of the wavelength swept light source X. Consequently, at a time when a center of the wavelength of the wavelength swept light Lx is the wavelength λ_{base}, the specific wavelength light λ_{bL}, the specific wavelength electrical signal λ_{bE}(t), and a specific wavelength signal λ_{b}(t) each have a maximum value.

### A/D Converter

AS in FIG. 1, the ADC 30 A/D-converts a trigger electrical signal WO and the interference electrical signal i_{E}(t) from the photoelectric conversion apparatus 10 at each time t, and outputs, in chronological order, the trigger signal tᵣ(t) and the interference signal i(t) that are composed of digital data. In addition, the ADC 30 A/D-converts the specific wavelength electrical signal λ_{bE}(t) from the photoelectric conversion apparatus 10 at each time t, and outputs the specific wavelength signals λ_{b}(t) composed of digital data, in chronological order.

### Signal Processing Apparatus

The signal processing apparatus 20 includes a microprocessor such as a digital service unit (DSU) and a CPU, and realizes, when the microprocessor and a program stored in the storage apparatus 32 are jointly operated, various types of signal processes for calculating a profile for the wavelength swept light Lx of the wavelength swept light source X, that is, in this case, a sweep frequency width Δf.

As illustrated in FIG. 8, the signal processing apparatus 20 realizes the target extraction unit 21, the relative frequency calculation unit 22, a predicted frequency calculation unit 24, a predicted wavelength calculation unit 25, and a swept wavelength width measurement unit 26, as main processing units. Note that each of the processing units of the signal processing apparatus 20 may be realized by dedicated hardware, that is, a signal processing circuit. Among these processing units, the target extraction unit 21 and the relative frequency calculation unit 22 are similar to those in FIG. 1, and detailed description thereof will be omitted here.

### Frequency Prediction Value Calculation Unit

The predicted frequency calculation unit 24 of the signal processing apparatus 20 illustrated in FIG. 8 will be described. The predicted frequency calculation unit 24 is configured to calculate, in chronological order, a predicted frequency fₚ(t) indicating an absolute frequency, from the relative frequency fᵣ(t) output from the relative frequency calculation unit 22, on the basis of the specific wavelength signal λ_{b}(t) from the ADC 30.

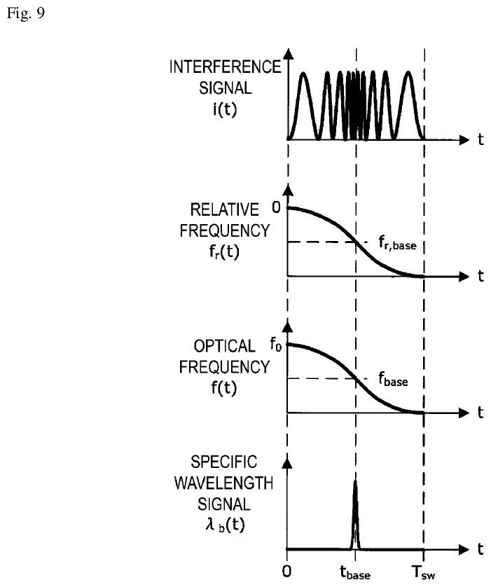

FIG. 9 is a signal waveform chart for calculating a predicted frequency value. FIG. 9 illustrates waveforms each indicating temporal changes in the intensity of the interference signal i(t), the relative frequency fᵣ(t) of the wavelength swept light Lx, the optical frequency f(t) of the wavelength swept light Lx, and the intensity of the specific wavelength signal λ_{b}(t). A scheme for calculating the predicted frequency value fₚ(t) in the predicted frequency calculation unit 24 will be described below with reference to FIG. 9.

As illustrated in FIG. 9, a peak time t_{base} of the specific wavelength signal λ_{b}(t) is a time at which a center frequency of the wavelength swept light Lx is a frequency f_{base}. At this time, Equation (14) below is satisfied.

$$\begin{matrix}Math . 14 & \\ f ( {t}_{base} ) = {f}_{base} = \frac{c}{{λ}_{base}} & ( 14 )\end{matrix}$$

A relative frequency fᵣ(t_{base}) (=f_{r, base}) corresponds to a frequency fᵣ(t_{base}), and thus, fᵣ(0)(=f₀) is expressed as in Equation (15) below. Furthermore, the center frequency of the wavelength swept light Lx is expressed as in Equation (16) below.

$$\begin{matrix} Math . 15 & \\ {f}_{0} = {f}_{r} ( 0 ) = {f}_{b a s e} - {f}_{r , base} = \frac{c}{{λ}_{b a s e}} - {f}_{r} ( {t}_{b a s e} ) & ( 15 ) \\ Math . 16 & \\ f ( t ) = {f}_{0} + {f}_{r} ( t ) = {f}_{base} - {f}_{r , base} + {f}_{r} ( t ) = \frac{c}{{λ}_{base}} - {f}_{r} ( {t}_{base} ) + {f}_{r} ( t ) & ( 16 )\end{matrix}$$

According to this scheme, the predicted frequency calculation unit 24 calculates a predicted (center) frequency, that is, the predicted frequency fₚ(t) of the wavelength swept light Lx in accordance with Equation (17) below.

$$\begin{matrix} Math . 17 & \\ {f}_{p} ( t ) = {f}_{0} + {f}_{r} ( t ) = {f}_{b a s e} - {f}_{r , b a s e} + {f}_{r} ( t ) = \frac{c}{{λ}_{b a s e}} - {f}_{r} ( {t}_{b a s e} ) + {f}_{r} ( t ) & ( 17 )\end{matrix}$$

### Predicted Wavelength Calculation Unit

The predicted wavelength calculation unit 25 of the signal processing apparatus 20 illustrated in FIG. 8 will be described. The predicted wavelength calculation unit 25 is configured to convert the predicted frequency fₚ(t) output from the predicted frequency calculation unit 24 into the predicted wavelength λₚ(t), in chronological order.

The predicted wavelength calculation unit 25 converts the predicted frequency fₚ(t) into the predicted wavelength λₚ(t) in accordance with Equation (18) below.

$$\begin{matrix}Math . 18 & \\ {λ}_{p} ( t ) = \frac{c}{{f}_{p} ( t )} & ( 18 )\end{matrix}$$

### Swept Wavelength Width Measurement Unit

The swept wavelength width measurement unit 26 of the signal processing apparatus 20 illustrated in FIG. 8 will be described. The swept wavelength width measurement unit 26 is configured to measure a difference between a maximum value and a minimum value of the predicted wavelength λₚ(t) output from the predicted wavelength calculation unit 25, as the swept wavelength width Δλ.

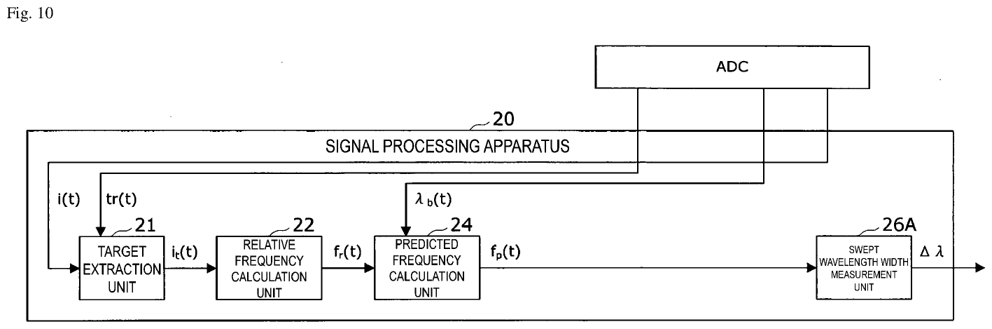

FIG. 10 is a block diagram illustrating another exemplary configuration of a signal processing apparatus according to the fourth embodiment. In FIG. 8, a case where the predicted wavelength λₚ(t) is determined by the predicted wavelength calculation unit 25 from the predicted frequency fₚ(t) and the swept wavelength width Δλ is subsequently determined, is described in an example, but the present invention is not limited to this case. For example, as illustrated in FIG. 10, the predicted wavelength calculation unit 25 is omitted from the configuration illustrated in FIG. 8, and a swept wavelength width measurement unit 26A may determine, in accordance with Equation (18) mentioned above, two predicted wavelengths λₚ(t) corresponding to a maximum value and a minimum value of the predicted frequency fₚ(t) output from the predicted frequency calculation unit 24, and measure a difference between the predicted wavelengths λₚ(t), as the swept wavelength width Δλ. Consequently, the predicted wavelength calculation unit 25 can be omitted, and the number of the predicted wavelengths λₚ(t) to be calculated can be significantly reduced, and thus, it is possible to reduce a processing amount in the signal processing apparatus 20, compared to the configuration illustrated in FIG. 8

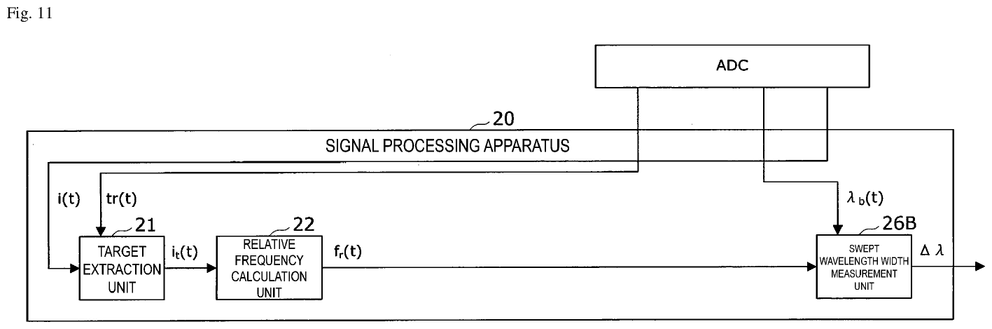

FIG. 11 is a block diagram illustrating another exemplary configuration of a signal processing apparatus according to the fourth embodiment. As illustrated in FIG. 11, the predicted frequency calculation unit 24 and the predicted wavelength calculation unit 25 are omitted from the configuration illustrated in FIG. 8, and a swept wavelength width measurement unit 26B may determine, in accordance with Equations (17) and (18) mentioned above, predicted wavelengths λₚ(t) corresponding to a maximum value and a minimum value of the relative frequency fᵣ(t) output from the relative frequency calculation unit 22, and measure a difference between the predicted wavelengths λₚ(t) as the swept wavelength width Δλ. Consequently, the predicted frequency calculation unit 24 and the predicted wavelength calculation unit 25 can be omitted, and the number of predicted frequencies fₚ(t) and predicted wavelengths λₚ(t) to be calculated can be significantly reduced, and thus, it is possible to significantly reduce a processing amount in the signal processing apparatus 20, compared to the configuration illustrated in FIG. 8.

### Effect of Fourth Embodiment

As described above, in the present embodiment, the photoelectric conversion apparatus 10 photoelectrically converts and outputs each of the interference light iL obtained as a result of interference of the wavelength swept light Lx output from the wavelength swept light source X in the interferometer 11, and a specific wavelength light λbL detected by the narrow band wavelength filter 13 from the wavelength swept light Lx, and the signal processing apparatus 20 calculates, in chronological order, the relative frequencies fᵣ(t) for interference signals i(t) obtained by photoelectric conversion of the interference light iL, calculates the predicted frequencies fₚ(t) for the relative frequencies fᵣ(t), on the basis of the detection timing of the specific wavelength light λ_{bL} obtained by photoelectric conversion of the specific wavelength light λ_{bL}, and measures a difference between the maximum value and the minimum value of the predicted wavelengths λₚ(t) corresponding to the obtained predicted frequencies fₚ(t), as the swept wavelength width Δλ of the wavelength swept light Lx.

Consequently, it is possible to measure the swept wavelength width Δλ of the wavelength swept light Lx with extremely high precision and accuracy, regardless of a sweeping speed of the wavelength swept light source X.

Furthermore, in the present embodiment, in the signal processing apparatus 20, the predicted frequency calculation unit 24 may calculate the predicted frequency fₚ(t), at each time t, of the relative frequency fᵣ(t) calculated by the relative frequency calculation unit 22, on the basis of the detection timing of the specific wavelength light λ_{bL}, the predicted wavelength calculation unit 25 may calculate the predicted wavelength λₚ(t) of the predicted frequency fₚ(t) at each time t, and the swept wavelength width measurement unit 26 may measure a difference between a maximum value and a minimum value of the predicted wavelength λₚ(t) as the swept wavelength width Δλ of the wavelength swept light Lx. Consequently, the swept wavelength width Δλ of the wavelength swept light Lx can be measured by a relatively simple process.

Furthermore, in the present embodiment, in the signal processing apparatus 20, the predicted frequency calculation unit 24 may calculate the predicted frequency fp(t), at each time t, of the relative frequency fᵣ(t) calculated by the relative frequency calculation unit 22, on the basis of the detection timing of the specific wavelength light λ_{bL}, and the swept wavelength width measurement unit 26A may calculate only two predicted wavelengths λₚ(t) corresponding to a maximum value and a maximum value of the predicted frequencies fₚ(t), and measure a difference between the two predicted wavelengths λₚ(t) as the swept wavelength width Δλ of the wavelength swept light Lx. Consequently, it is possible to reduce a processing load for calculating the predicted wavelength λₚ(t) in the signal processing apparatus 20.

Furthermore, in the present embodiment, in the signal processing apparatus 20, the predicted frequency calculation unit 24 may calculate only two predicted frequencies fₚ(t) corresponding to a maximum value and a maximum value of the relative frequencies fᵣ(t) calculated by the relative frequency calculation unit 22, on the basis of the detection timing of the specific wavelength light λ_{bL}, and the swept wavelength width measurement unit 26B may calculate only two predicted wavelengths λₚ(t) corresponding to a maximum value and a maximum value of the predicted frequencies fₚ(t), and measure a difference between the two predicted wavelengths λₚ(t), as the swept wavelength width Δλ of the wavelength swept light Lx. Consequently, it is possible to reduce a processing load for calculating the predicted frequency fₚ(t) and the predicted wavelength λₚ(t) in the signal processing apparatus 20.

The present embodiment is described on the assumption that the specific wavelength light λ_{bL}, the specific wavelength electrical signal λ_{bE}(t), and the specific wavelength signal λ_{b}(t) have a peak at a time when the center of the wavelength of the wavelength swept light Lx output from the wavelength swept light source X to be measured is λbase. However, in the ADC 30, the peak of the specific wavelength electrical signal λ_{bE}(t) may not always be sampled. That is, the peak time t_{base} of the specific wavelength electrical signal λ_{bE}(t) may not be synchronized with a sampling time of the ADC 30, but may be between two adjacent sampling times.

Consequently, for example, the predicted frequency calculation unit 24 illustrated in FIGS. 8 and 10 and the swept wavelength width measurement unit 26B illustrated in FIG. 11 may interpolate the vicinity of the peak of the specific wavelength electrical signal λ_{bE}(t) to accurately detect the peak time t_{base}. Specifically, it may be possible to employ a zero padding method to interpolate the specific wavelength signal λ_{b}(t) between two adjacent sampling times, and to use a peak time of the obtained interpolated signal as an estimation value of the peak time t_{base}. Furthermore, in addition to the zero putting method, it may be possible to use a quadratic function, a Gaussian function, a Lorentzian function, or the like for fitting, on the basis of data (for example, about three to ten pieces of data) in the vicinity of the peak of the specific wavelength signal λ_{b}(t), and to use an obtained peak time of the function as an estimation value of the peak time t_{base}.

### Fifth Embodiment

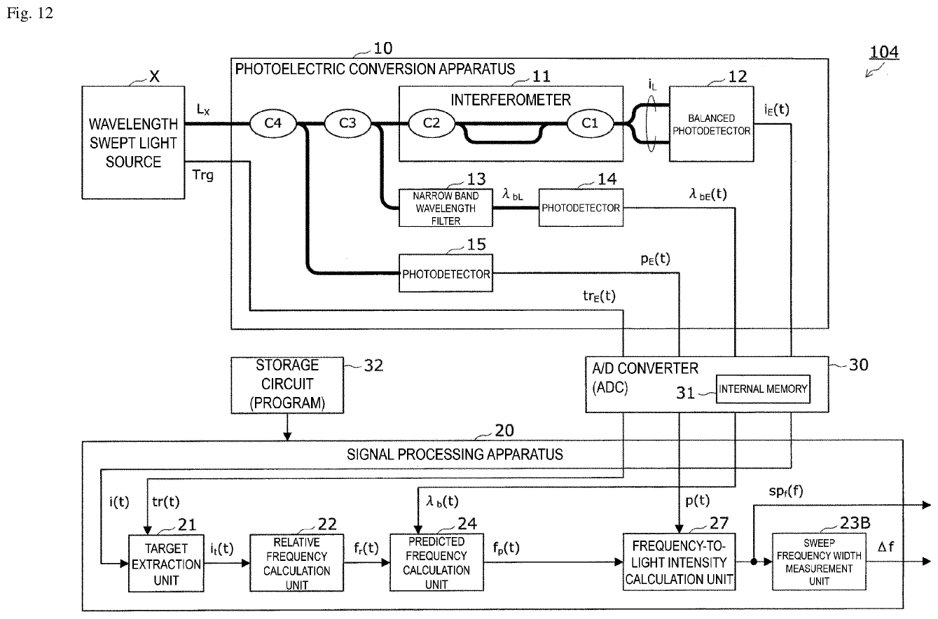

Next, a wavelength swept light measurement system 104 according to a fifth embodiment of the present invention will be described with reference to FIG. 12. FIG. 12 is a block diagram illustrating a configuration of a wavelength swept light measurement system according to the fifth embodiment.

As illustrated in FIG. 12, in the present embodiment, the predicted wavelength calculation unit 25 of the signal processing apparatus 20 is omitted from the configuration according to the fourth embodiment illustrated in FIG. 8, and a photodetector 15 that measures a light intensity of the wavelength swept light Lx is added to the photoelectric conversion apparatus 10, so as to calculate a change in the light intensity of the wavelength swept light Lx with respect to the frequency and obtain the sweep frequency width Δf for a resolution of a depth distance measurement method, on the basis of the obtained frequency-to-light intensity property (frequency spectrum).

### Photoelectric Conversion Apparatus

In addition to the interferometer 11, the balanced photodetector 12, the narrow band wavelength filter 13, and the photodetector 14 as with the configuration illustrated in FIG. 8, the photoelectric conversion apparatus 10 includes the photodetector 15 that detects the light intensity of the wavelength swept light Lx.

The wavelength swept light Lx is branched into two light beams by a coupler C4, and one of the branched light beams is further branched by the coupler C3, as with the configuration illustrated in FIG. 8, to be input to the interferometer 11 and the narrow band wavelength filter 13. The other one of the branched light beams is photoelectrically converted into a light intensity electrical signal p_{E}(t) by the photodetector 15.

### A/D Converter

As in FIG. 8, the ADC 30 A/D-converts the trigger electrical signal t_{rE}(t), the interference electrical signal i_{E}(t), and the specific wavelength electrical signal λ_{bE} from the photoelectric conversion apparatus 10 at each time t, and outputs the trigger signal tᵣ(t), the interference signal i(t), and the specific wavelength signal λ_{b}(t) that are composed of digital data, in chronological order. In addition, the ADC 30 A/D-converts the light intensity electrical signal p_{E}(t) from the photoelectric conversion apparatus 10 at each time t, and outputs light intensity P(t) composed of digital data, in chronological order.

### Signal Processing Apparatus

The signal processing apparatus 20 includes a microprocessor such as a digital service unit (DSU) and a CPU, and realizes, when the microprocessor and a program stored in the storage apparatus 32 are jointly operated, various types of signal processes for calculating a profile for the wavelength swept light Lx of the wavelength swept light source X, that is, in this case, a sweep frequency width Δf.

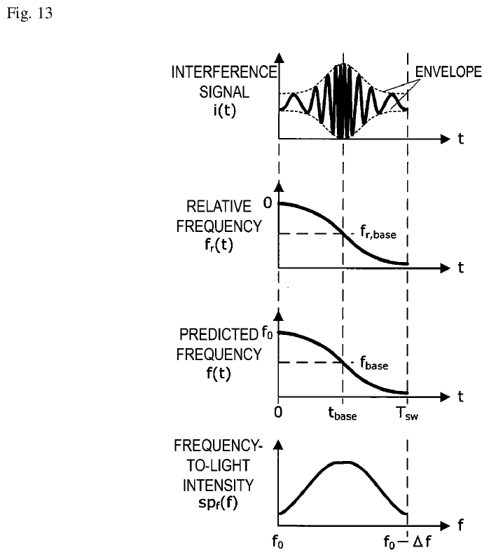

FIG. 13 is a signal waveform chart for a sweep frequency width calculation operation. FIG. 13 illustrates the intensity of the interference signal i(t), the relative frequency fᵣ(t) indicating the optical spectrum, the predicted frequency fₚ(t), and the light intensity p(t).

In each of the embodiments described above, for ease of understanding, a case is described where the interference signal i(t) is constant over time, however, the interference signal i(t) is actually not constant over time, but varies with respect to time, as illustrated in FIG. 13. Note that, it is assumed that the wavelength swept light source X outputs substantially the same wavelength swept light Lx in each sweep operation. That is, it is assumed that the light intensity for each frequency of the wavelength swept light Lx, that is, the optical spectrum of the wavelength swept light source X to be measured, is substantially constant in each sweep operation.

In depth distance measurement methods such as an FMCW radar method, an SS-OCT method, and an OFDR method, a resolution of the depth distance is inversely proportional to the sweep frequency width Δf of the wavelength swept light Lx, and substantially depends on a shape of the optical spectrum of the wavelength swept light Lx. The following description states that the width of the optical spectrum of the wavelength swept light Lx has an important influence on the performance of depth distance measurement methods such as the FMCW radar method, the SS-OCT method, and the OFDR method.

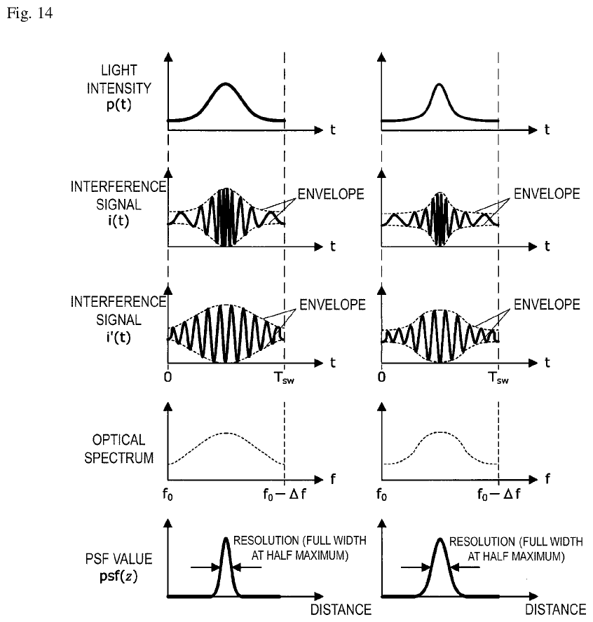

FIG. 14 is a signal waveform chart showing a relationship between an optical spectrum and a resolution of depth information. FIG. 14 illustrates the light intensity p(t) for the wavelength swept light Lx, the interference signal i(t), a rescaled interference signal i′(t), the relative frequency fᵣ(t) indicating the optical spectrum, and a point spread function value PSF.

According to the reference literature mentioned above, when a coherence length does not differ for each frequency of the light, an envelope of the interference signal i(t) coincides with a shape of the light intensity p(t). FIG. 14 illustrates an interference signal obtained when the wavelength swept light source X in which a frequency f of the wavelength swept light Lx does not linearly change with respect to the time t (is not frequency-linear) is used. In such a case, a resealing process described in the reference literature is performed to have a frequency-linear property.

In the depth distance measurement methods such as the FMCW radar method, the SS-OCT method, and the OFDR method, the rescaled interference signal i′(t) is Fourier-transformed to obtain depth information.

The depth information has one peak with respect to one reflection surface. A signal for the one reflection surface is called a point spread function (PSF). The interference signal i′(t) generated by one reflection surface is an AM-modulated signal obtained by resealing the light intensity p(t) to have a sine wave having a frequency proportional to a magnitude of a position z on the reflection surface. The PSF value is a result of the Fourier transform of the interference signal i′(t), and thus, the shape of the point spread function PSF coincides with the shape of the frequency obtained by Fourier transform of the interference signal i′(t).

A distance L on the horizontal axis of the graph of the point spread function PSF illustrated in FIG. 14 is proportional to the frequency obtained by Fourier transform of the interference signal i′(t). A distance Δz with respect to a frequency 1/T_{sw} can be calculated by Equation (19) below. Consequently, a distance z corresponding to a frequency n/T_{sw} can be calculated by Equation (20) below.

$$\begin{matrix}Math . 19 & \\ Δ z = \frac{c}{2 \cdot Δ f} & ( 19 )\end{matrix}$$

where c is a speed of light.

$$\begin{matrix}Math . 20 & \\ z = n \cdot Δ z = n \cdot \frac{c}{2 \cdot Δ f} & ( 20 )\end{matrix}$$

A time axis t′ of the resealed interference signal i′(t) is proportional to the frequency of the light, and thus, the envelope of the interference signal i(t) coincides with the shape of the optical spectrum of the wavelength swept light Lx. That is, it can be understood that a result of the Fourier transform of a spectral shape of the light coincides with the shape of the point spread function PSF. Thus, as the optical spectrum is wider, a width of the point spread function PSF is narrower, and thus, the resolution of the depth information increases. FIG. 14 illustrates the full width at half maximum of the PSF in an example of the resolution and illustrates that, as the optical spectrum of the wavelength swept light Lx is wider, a PSF width is narrower, that is, the resolution is higher.

The sweep frequency width Δf of the wavelength swept light source X and the resolution of the depth information (distance) will be also described below. Discrete Fourier transform is usually used for the Fourier transform of the interference signal i(t) in determining the depth information, and frequencies of the discrete Fourier transform are expressed by an integer, and an interval (that is, “11”) between the frequencies is 1/T_{sw} at an actual frequency. Thus, the depth information is expressed in increments of a frequency 1/T_{sw}. n appearing in the equation z=n*Δz=n*c/(2*Δf) expressed above represents a frequency of the discrete Fourier transform, and the distance z is expressed in increments of c/(2*Δf). This indicates that, as the sweep frequency width Δf of the wavelength swept light source X is wider, the resolution of the depth information (distance) increases in inverse proportion to the sweep frequency width Δf.

As illustrated in FIG. 12, the signal processing apparatus 20 realizes the target extraction unit 21, the relative frequency calculation unit 22, the predicted frequency calculation unit 24, a frequency-to-light intensity calculation unit 27, and a sweep frequency width measurement unit 23B, as main processing units. Note that each of the processing units of the signal processing apparatus 20 may be realized by dedicated hardware, that is, a signal processing circuit. Among these processing units, the target extraction unit 21, the relative frequency calculation unit 22, and the predicted frequency calculation unit 24 are similar to those in FIG. 8, and detailed description thereof will be omitted here.

### Frequency-to-Light Intensity Calculation Unit

The frequency-to-light intensity calculation unit 27 is configured to calculate a frequency-to-light intensity sp_{f}(f), that is, a frequency spectrum, indicating the light intensity of the wavelength swept light Lx at each frequency of the wavelength swept light Lx, on the basis of the predicted frequency fₚ(t) from the predicted frequency calculation unit 24 and the light intensity p(t) from the ADC 30. In the frequency-to-light intensity calculation unit 27, the frequency-to-light intensity sp_{f}(f) may be output from the signal processing apparatus 20, in accordance with a request from a user.

The frequency-to-light intensity sp_{f}(f) is a value representing the light intensity for the wavelength swept light Lx at each frequency, and thus, may be regarded as the frequency spectrum of the wavelength swept light Lx. In a method for obtaining the frequency-to-light intensity sp_{f}(f), it may be possible to combine the predicted frequency fₚ(t) and the light intensity p(t) at the same time t to use the light intensity p(t) for the predicted frequency fₚ(t) as the frequency-to-light intensity sp_{f}(f), for example. In another method, it may be possible to determine an inverse function predicted frequency t(f) of the predicted frequency fₚ(t) and use p(t(f)) as the frequency-to-light intensity sp_{f}(f). In the both methods, the frequency-to-light intensity sp_{f}(f) is discrete data obtained from sampling by the ADC 30, and thus, may be interpolated, as necessary.

### Sweep Frequency Width Measurement Unit

The sweep frequency width measurement unit 23B is configured to measure and output the sweep frequency width Δf of the wavelength swept light Lx from the frequency-to-light intensity sp_{f}(f). For example, it may be possible to determine the sweep frequency width Δf as the full width at half maximum or as a width that is 1/e² of the maximum value of the frequency-to-light intensity spf(f).

### Effect of Fifth Embodiment

As described above, in the present embodiment, the photoelectric conversion apparatus 10 photoelectrically converts each of the wavelength swept light Lx and the specific wavelength light λ_{bL} detected by the narrow band wavelength filter 13 from the wavelength swept light Lx, and the signal processing apparatus 20 calculates the frequency-to-light intensity sp_{f}(f) indicating the light intensity of the wavelength swept light Lx for each frequency of the wavelength swept light Lx, on the basis of the predicted frequency fₚ(t) obtained in much the same way as the above description and the detection timing of the specific wavelength light λ_{bL} detected by the photoelectric conversion apparatus 10, and measures the sweep frequency width Δf of the wavelength swept light Lx, on the basis of the frequency-to-light intensity sp_{f}(f).

Consequently, it is possible to measure the sweep frequency width Δf of the wavelength swept light source X for the resolution of depth distance measurement methods such as the FMCW radar method, the SS-OCT method, and the OFDR method. Furthermore, when the frequency-to-light intensity sp_{f}(f) is output to the outside of the signal processing apparatus 20, it is also possible to obtain a frequency spectrum for the wavelength swept light Lx of the wavelength swept light source X.

### Sixth Embodiment

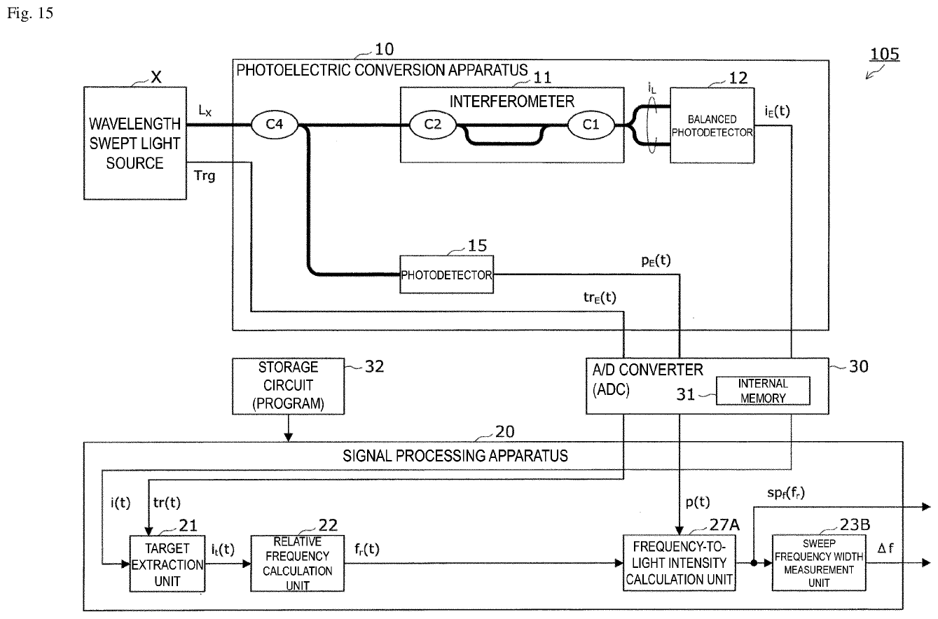

Next, a wavelength swept light measurement system 105 according to a sixth embodiment of the present invention will be described with reference to FIG. 15. FIG. 15 is a block diagram illustrating a configuration of the wavelength swept light measurement system according to the sixth embodiment.

As illustrated in FIG. 15, in the present embodiment, the predicted frequency calculation unit 24 of the signal processing apparatus 20 is omitted from the configuration according to the fifth embodiment illustrated in FIG. 12, and thus, the relative frequency fᵣ(t) of the wavelength swept light Lx output from the relative frequency calculation unit 22 is used as the optical spectrum of the wavelength swept light Lx to calculate the frequency-to-light intensity sp_{f}(f). Consequently, a processing content in the frequency-to-light intensity calculation unit 27 differs from that in the fifth embodiment, and thus, the frequency-to-light intensity calculation unit 27 is referred to as a frequency-to-light intensity calculation unit 27A in the present embodiment.

### Photoelectric Conversion Apparatus

As illustrated in FIG. 15, the configuration of the photoelectric conversion apparatus 10 is different from the configuration illustrated in FIG. 12 in that the coupler C3, the narrow band wavelength filter 13, and the photodetector 14 are omitted.

### A/D Converter

The specific wavelength electrical signal λ_{bE}(t) from the photoelectric conversion apparatus 10 is omitted from the configuration illustrated in FIG. 12, and thus, as illustrated in FIG. 15, the ADC 30 A/D-converts the trigger electrical signal tr_{E}(t), the interference electrical signal i_{E}(t), and the light intensity electrical signal p_{E} from the photoelectric conversion apparatus 10 at each time t, to output the trigger signal tr(t), the interference signal i(t), and the light intensity P(t) that are composed of digital data, in chronological order.

### Signal Processing Apparatus

The signal processing apparatus 20 includes a microprocessor such as a digital service unit (DSU) and a CPU, and realizes, when the microprocessor and a program stored in the storage apparatus 32 are jointly operated, various types of signal processes for calculating a profile for the wavelength swept light Lx of the wavelength swept light source X, that is, in this case, a sweep frequency width Δf.

As illustrated in FIG. 15, the signal processing apparatus 20 realizes the target extraction unit 21, the relative frequency calculation unit 22, the frequency-to-light intensity calculation unit 27A, and the sweep frequency width measurement unit 23B, as main processing units. The predicted frequency calculation unit 24 is omitted from the configuration illustrated in FIG. 12, and thus, the relative frequency fᵣ(t) output from the relative frequency calculation unit 22 is input to the frequency-to-light intensity calculation unit 27A. Among these processing units, the target extraction unit 21, the relative frequency calculation unit 22, and the sweep frequency width measurement unit 23B are similar to those in FIG. 12, and detailed description thereof will be omitted here.

### Frequency-to-Light Intensity Calculation Unit

The frequency-to-light intensity calculation unit 27A is configured to calculate a frequency-to-light intensity sp_{f}(fᵣ), that is, a frequency spectrum, indicating the light intensity of the wavelength swept light Lx for each relative frequency fᵣ(t) of the wavelength swept light Lx, on the basis of the relative frequency fᵣ(t) from the relative frequency calculation unit 22 and the light intensity p(t) from the ADC 30. In the frequency-to-light intensity calculation unit 27A, the frequency-to-light intensity sp_{f}(fᵣ) may be output from the signal processing apparatus 20, in accordance with a request from a user.

### Effect of Sixth Embodiment

As described above, in the present embodiment, the signal processing apparatus 20 calculates, on the basis of the relative frequencies fᵣ(t) obtained as in FIG. 1 and the light intensity p(t) of the wavelength swept light Lx obtained by the photoelectric conversion apparatus 10, the frequency-to-light intensity sp_{f}(fᵣ) indicating the light intensity of the wavelength swept light Lx for each relative frequency fᵣ(t) of the wavelength swept light Lx, to measure the sweep frequency width Δf of the wavelength swept light Lx, on the basis of the frequency-to-light intensity sp_{f}(fᵣ).

Consequently, the sweep frequency width Δf of the wavelength swept light source X for the resolution of depth distance measurement methods such as the FMCW radar method, the SS-OCT method, and the OFDR method, can be measured by a simpler configuration than in FIG. 15. Thus, it is possible to reduce the amount of hardware of the photoelectric conversion apparatus 10 and the processing load of the signal processing apparatus 20. Furthermore, when the frequency-to-light intensity sp_{f}(fᵣ) is output to the outside of the signal processing apparatus 20, it is also possible to obtain a frequency spectrum for the wavelength swept light Lx of the wavelength swept light source X.

### Seventh Embodiment

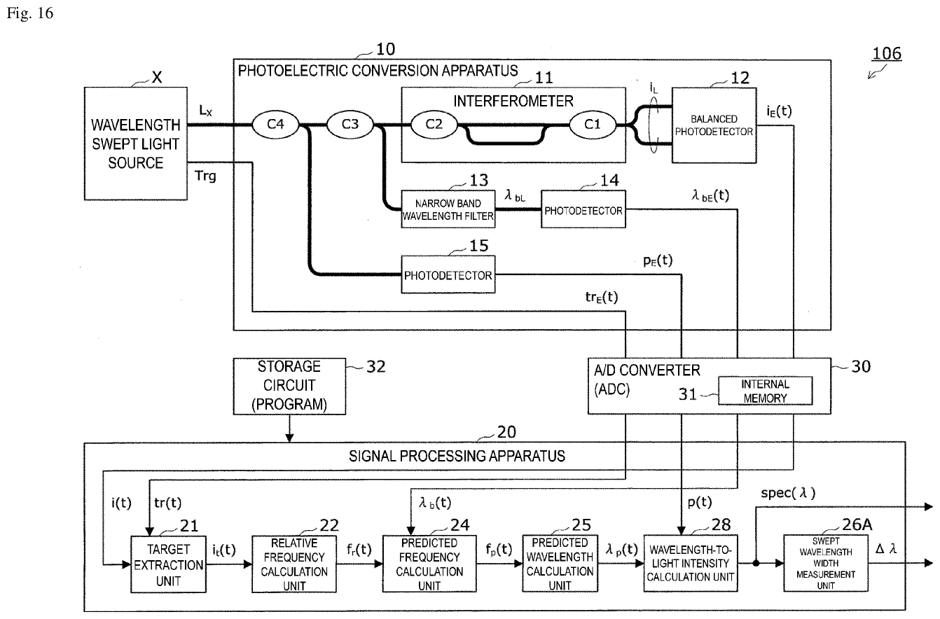

Next, a wavelength swept light measurement system 106 according to a seventh embodiment of the present invention will be described with reference to FIG. 16. FIG. 16 is a block diagram illustrating a configuration of a wavelength swept light measurement system according to the seventh embodiment.

As illustrated in FIG. 16, compared to the fourth embodiment in FIG. 8, the photodetector 15 is added to the photoelectric conversion apparatus 10 in the present embodiment, and thus, the photoelectric conversion apparatus 10 measures the light intensity p(t) of the wavelength swept light Lx, calculates, on the basis of the obtained light intensity p(t) and the predicted wavelength λₚ(t), a wavelength-to-light intensity spec(λ) indicating the light intensity p(t) of the wavelength swept light Lx for each predicted wavelength λₚ(t), and measures the swept wavelength width Δλ of the wavelength swept light Lx, on the basis of the wavelength-to-light intensity spec(λ).

Note that, in the present embodiment, compared to the fifth embodiment in FIG. 12, the predicted wavelength calculation unit 25 is added behind the predicted frequency calculation unit 24 of the signal processing apparatus 20, a wavelength-to-light intensity calculation unit 28 is provided instead of the frequency-to-light intensity calculation unit 27, and the swept wavelength width measurement unit 26A is provided instead of the sweep frequency width measurement unit 23B.

Note that the photoelectric conversion apparatus 10, the ADC 30, and the storage apparatus 32 in the wavelength swept light measurement system 106 according to the present embodiment are similar to those in the fifth embodiment, and thus, detailed description thereof will be omitted here.

### Signal Processing Apparatus

The signal processing apparatus 20 includes a microprocessor such as a digital service unit (DSU) and a CPU, and realizes, when the microprocessor and a program stored in the storage apparatus 32 are jointly operated, various types of signal processes for calculating a profile for the wavelength swept light Lx of the wavelength swept light source X, that is, in this case, a swept wavelength width Δλ.

As illustrated in FIG. 16, the signal processing apparatus 20 realizes the target extraction unit 21, the relative frequency calculation unit 22, the predicted frequency calculation unit 24, the predicted wavelength calculation unit 25, the wavelength-to-light intensity calculation unit 28, and the swept wavelength width measurement unit 26A, as main processing units. Among these processing units, the target extraction unit 21, the relative frequency calculation unit 22, the predicted frequency calculation unit 24, and the predicted wavelength calculation unit 25 are similar to those in FIG. 8, and detailed description thereof will be omitted here.

### Wavelength-to-Light Intensity Calculation Unit

The wavelength-to-light intensity calculation unit 28 is configured to calculate the wavelength-to-light intensity spec(λ), that is, a wavelength spectrum, indicating the light intensity of the wavelength swept light Lx for individual wavelengths, on the basis of the predicted wavelength λₚ(t) from the predicted wavelength calculation unit 25 and the light intensity p(t) from the ADC 30. In the wavelength-to-light intensity calculation unit 28, the wavelength-to-light intensity spec(λ) may be output from the signal processing apparatus 20, in accordance with a request from a user.

### Swept Wavelength Width Measurement Unit

The swept wavelength width measurement unit 26A is configured to measure a difference between a maximum value and a minimum value of the wavelength-to-light intensity spec(λ) output from the wavelength-to-light intensity calculation unit 28, as the swept wavelength width Δλ.

### Effect of Seventh Embodiment

As described above, in the present embodiment, the signal processing apparatus 20 calculates the wavelength-to-light intensity spec(λ) indicating the light intensity of the wavelength swept light Lx for the predicted wavelength λₚ(t), on the basis of the predicted wavelength λₚ(t) obtained as in FIG. 8 and the light intensity p(t) of the wavelength swept light Lx obtained by the photoelectric conversion apparatus 10, and measures the swept wavelength width Δλ of the wavelength swept light Lx, on the basis of the wavelength-to-light intensity spec(λ).

Consequently, it is possible to measure the swept wavelength width Δλ of the wavelength swept light Lx with extremely high precision and accuracy, regardless of a sweeping speed of the wavelength swept light source X. Furthermore, when the wavelength-to-light intensity spec(λ) is output to the outside of the signal processing apparatus 20, it is also possible to obtain a wavelength spectrum for the wavelength swept light Lx of the wavelength swept light source X.

### Eighth Embodiment

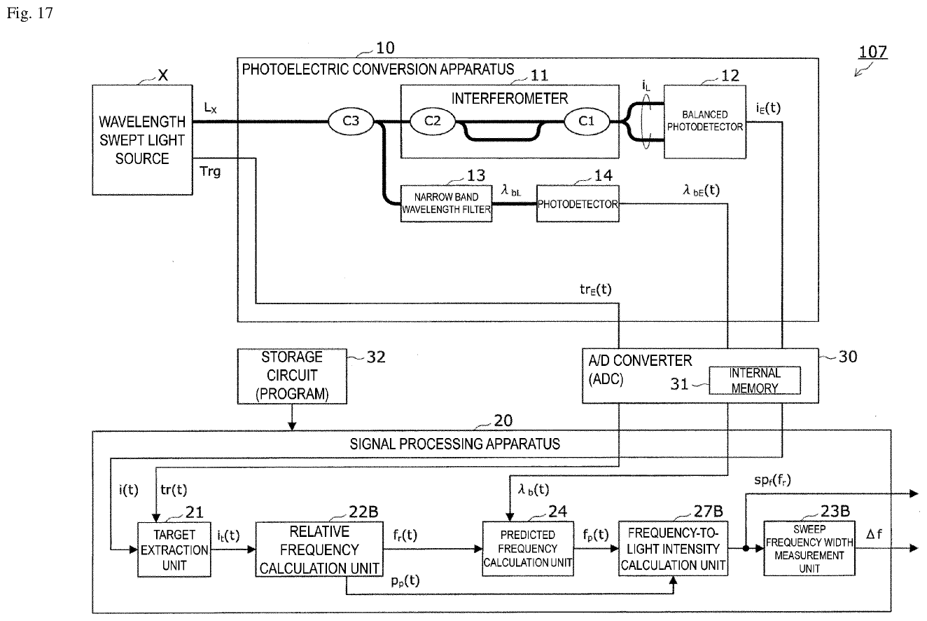

Next, a wavelength swept light measurement system 107 according to an eighth embodiment of the present invention will be described with reference to FIG. 17. FIG. 17 is a block diagram illustrating a configuration of the wavelength swept light measurement system according to the eighth embodiment.

As illustrated in FIG. 17, in the configuration of the present embodiment, the light intensity p(t) in the fifth embodiment of FIG. 12 is not predicted by the photoelectric conversion apparatus 10, but is predicted from the target interference signal iₜ(t) by the signal processing apparatus 20, and thus, instead of the relative frequency calculation unit 22 of FIG. 12, a relative frequency calculation unit 22B is applied to the configuration of the present embodiment. Consequently, compared to FIG. 12, the coupler C4 and the photodetector 15 may be omitted from FIG. 12, and a number of channels of the ADC 30 may be reduced, and thus, the photoelectric conversion apparatus 10 and the ADC 30 may have configurations similar to those in FIG. 8.

### Signal Processing Apparatus

The signal processing apparatus 20 includes a microprocessor such as a digital service unit (DSU) and a CPU, and realizes, when the microprocessor and a program stored in the storage apparatus 32 are jointly operated, various types of signal processes for calculating a profile for the wavelength swept light Lx of the wavelength swept light source X, that is, in this case, a sweep frequency width Δf.

As illustrated in FIG. 17, the signal processing apparatus 20 realizes the target extraction unit 21, the relative frequency calculation unit 22B, the predicted frequency calculation unit 24, a frequency-to-light intensity calculation unit 27B, and the sweep frequency width measurement unit 23B, as main processing units. Among these processing units, the target extraction unit 21, the predicted frequency calculation unit 24, and the sweep frequency width measurement unit 23B are similar to those in FIG. 8, and detailed description thereof will be omitted here.

### Relative Frequency Calculation Unit

The relative frequency calculation unit 22B is configured to calculate the relative frequency fᵣ(t) and the light intensity pₚ(t) of the wavelength swept light Lx, on the basis of the target interference signal iₜ(t) output from the target extraction unit 21.

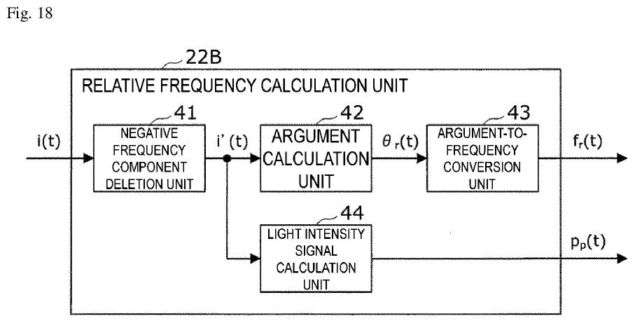

FIG. 18 is a block diagram illustrating an exemplary configuration of a relative frequency calculation unit according to the eighth embodiment. As illustrated in FIG. 18, the relative frequency calculation unit 22B includes the negative frequency component deletion unit 41, the argument calculation unit 42, the argument-to-frequency conversion unit 43, and a light intensity calculation unit 44, as main processing units.

Among these processing units, the negative frequency component deletion unit 41, the argument calculation unit 42, and the argument-to-frequency conversion unit 43 are similar to those in FIG. 4, and detailed description thereof will be omitted here.

The light intensity calculation unit 44 calculates an intensity of a signal i′(t) output from the negative frequency component deletion unit 41 and outputs a result of the calculation as the light intensity pₚ(t) of the wavelength swept light Lx. The signal i′(t) is a complex number, and the light intensity pₚ(t) can be calculated, for example, by Equation (21) below.

Math. 21

pₚ(t)=√R̅(̅i̅′̅(̅t̅)̅)̅²̅+̅I̅(̅i̅′̅(̅t̅)̅)̅ (21)

where R(x) and I(x) represent a real part and an imaginary part of x, respectively.

### Frequency-to-Light Intensity Calculation Unit

The frequency-to-light intensity calculation unit 27B is configured to calculate the frequency-to-light intensity spf(fᵣ), that is, a frequency spectrum, indicating the light intensity of the wavelength swept light Lx for the relative frequency fᵣ(t), on the basis of the predicted frequency fₚ(t) from the predicted frequency calculation unit 24 and the light intensity pₚ(t) output from the relative frequency calculation unit 22B.

### Effect of Eighth Embodiment

As described above, in the present embodiment, the signal processing apparatus 20 calculates, on the basis of the detection timing of the specific wavelength light λ_{bL} detected by the photoelectric conversion apparatus 10 and the relative frequencies fᵣ(t), the predicted frequency fₚ(t) indicating an absolute frequency for these relative frequencies fᵣ(t), calculates the light intensity pₚ(t) of the wavelength swept light Lx from the target interference signal iₜ(t), calculates the frequency-to-light intensity sp_{f}(f) indicating the light intensity of the wavelength swept light Lx for the predicted frequency fₚ(t), on the basis of the light intensity pₚ(t) and the predicted frequency fₚ(t), and measures the sweep frequency width Δf, on the basis of the frequency-to-light intensity sp_{f}(f).

Consequently, compared to the fifth embodiment of FIG. 12, the coupler C4 and the photodetector 15 of the photoelectric conversion apparatus 10 are not required, and the number of channels of the ADC 30 may be reduced, and thus, it is possible to simplify the configuration of the photoelectric conversion apparatus 10 as well as the ADC 30 to a level similar to that in FIG. 8. Furthermore, when the frequency-to-light intensity sp_{f}(f) is output to the outside of the signal processing apparatus 20, it is also possible to obtain a frequency spectrum for the wavelength swept light Lx of the wavelength swept light source X.

### Ninth Embodiment

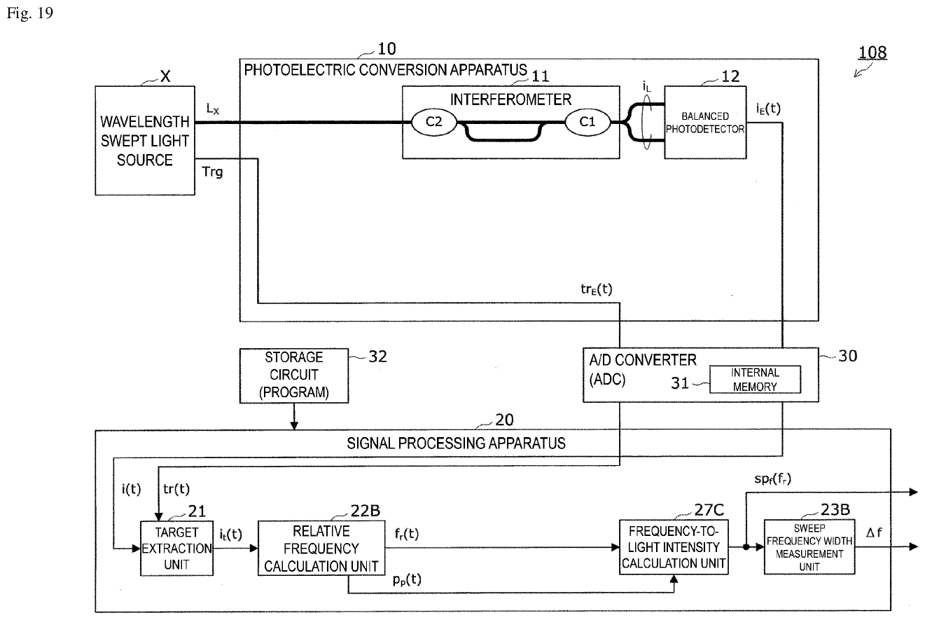

Next, a wavelength swept light measurement system 108 according to a ninth embodiment of the present invention will be described with gathering FIG. 19. FIG. 19 is a block diagram illustrating a configuration of the wavelength swept light measurement system according to the ninth embodiment.

In the eighth embodiment of FIG. 18, a case where the relative frequency calculation unit 22B is applied instead of the relative frequency calculation unit 22 illustrated in FIG. 12 is described in an example. As illustrated in FIG. 19, in the present embodiment, the relative frequency calculation unit 22B is applied instead of the relative frequency calculation unit 22 in FIG. 15, the relative frequency fᵣ(t) of the wavelength swept light Lx output from the relative frequency calculation unit 22B is employed for the optical spectrum of the wavelength swept light Lx, and the frequency-to-light intensity sp_{f}(fᵣ) is calculated on the basis of the light intensity pₚ(t) calculated by the relative frequency calculation unit 22B. Consequently, compared to FIG. 15, the coupler C4 and the photodetector 15 can be omitted, and the number of channels of the ADC 30 can be reduced, and thus, the photoelectric conversion apparatus 10 and the ADC 30 can have configurations similar to those in FIG. 1.

### Signal Processing Apparatus

The signal processing apparatus 20 includes a microprocessor such as a digital service unit (DSU) and a CPU, and realizes, when the microprocessor and a program stored in the storage apparatus 32 are jointly operated, various types of signal processes for calculating a profile for the wavelength swept light Lx of the wavelength swept light source X, that is, in this case, a sweep frequency width Δf.

As illustrated in FIG. 19, the signal processing apparatus 20 realizes the target extraction unit 21, the relative frequency calculation unit 22B, a frequency-to-light intensity calculation unit 27C, and the sweep frequency width measurement unit 23B, as main processing units. Among these processing units, the target extraction unit 21, the relative frequency calculation unit 22B, and the sweep frequency width measurement unit 23B are similar to those in FIG. 17, and detailed description thereof will be omitted here.

### Frequency-to-Light Intensity Calculation Unit

The frequency-to-light intensity calculation unit 27C is configured to calculate the frequency-to-light intensity sp_{f}(fᵣ), that is, a frequency spectrum, indicating the light intensity of the wavelength swept light Lx for the relative frequency fᵣ(t), on the basis of the relative frequency fᵣ(t) and the light intensity pₚ(t) of the wavelength swept light Lx output from the relative frequency calculation unit 22B.

### Effect of Ninth Embodiment

As described above, in the present embodiment, the signal processing apparatus 20 calculates the light intensity pₚ(t) of the wavelength swept light Lx from the target interference signal iₜ(t), calculates the frequency-to-light intensity sp_{f}(fᵣ) indicating the light intensity of the wavelength swept light Lx for the relative frequency fᵣ(t), on the basis of the light intensity pₚ(t) and the relative frequency fᵣ(t), and measures the sweep frequency width Δf on the basis of the frequency-to-light intensity sp_{f}(fᵣ).

Consequently, compared to the sixth embodiment of FIG. 15, the coupler C4 and the photodetector 15 of the photoelectric conversion apparatus 10 are not required, and the number of channels of the ADC 30 can be reduced, and thus, it is possible to simplify the configuration of the photoelectric conversion apparatus 10 as well as the ADC 30 to a level similar to that in FIG. 1. Furthermore, when the frequency-to-light intensity sp_{f}(fᵣ) is output to the outside of the signal processing apparatus 20, it is also possible to obtain a frequency spectrum for the wavelength swept light Lx of the wavelength swept light source X.

### Tenth Embodiment

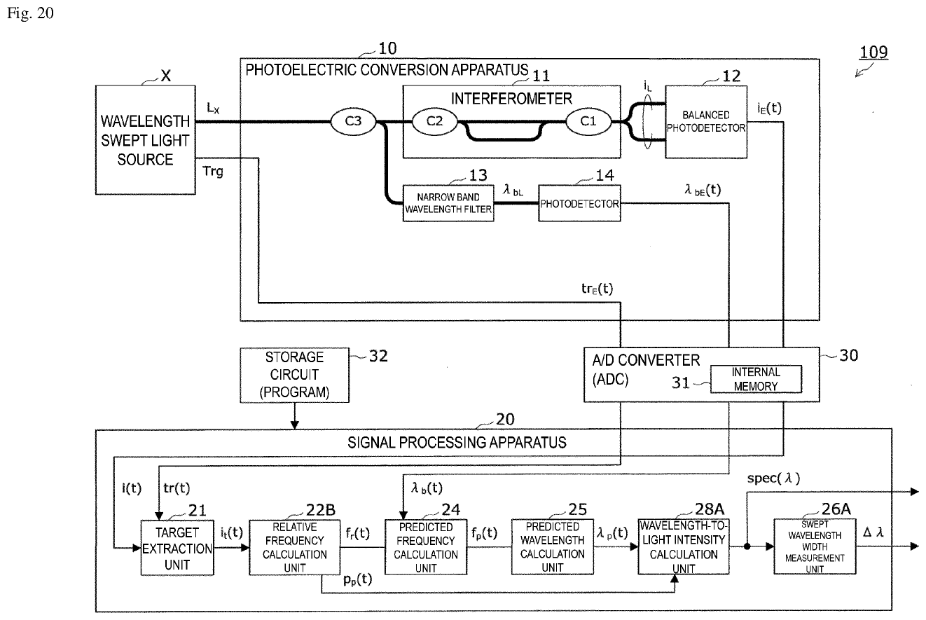

Next, a wavelength swept light measurement system 109 according to a tenth embodiment of the present invention will be described with reference to FIG. 20. FIG. 20 is a block diagram illustrating a configuration of the wavelength swept light measurement system according to the tenth embodiment.

As illustrated in FIG. 20, in the present embodiment, the relative frequency calculation unit 22B is applied instead of the relative frequency calculation unit 22 in FIG. 16, and the wavelength-to-light intensity spec(λ) is calculated on the basis of the light intensity pₚ(t) calculated by the relative frequency calculation unit 22B. Consequently, compared to FIG. 16, the coupler C4 and the photodetector 15 can be omitted, and the number of channels of the ADC 30 can be reduced, and thus, the photoelectric conversion apparatus 10 and the ADC 30 can have configurations similar to those in FIG. 8.

### Signal Processing Apparatus

The signal processing apparatus 20 includes a microprocessor such as a digital service unit (DSU) and a CPU, and realizes, when the microprocessor and a program stored in the storage apparatus 32 are jointly operated, various types of signal processes for calculating a profile for the wavelength swept light Lx of the wavelength swept light source X, that is, in this case, a swept wavelength width Δλ.

As illustrated in FIG. 20, the signal processing apparatus 20 realizes the target extraction unit 21, the relative frequency calculation unit 22B, the predicted frequency calculation unit 24, the predicted wavelength calculation unit 25, a wavelength-to-light intensity calculation unit 28A, and the swept wavelength width measurement unit 26A, as main processing units. Among these processing units, the target extraction unit 21, the predicted frequency calculation unit 24, the predicted wavelength calculation unit 25, and the swept wavelength width measurement unit 26A are similar to those in FIG. 16, and detailed description thereof will be omitted here. Furthermore, the relative frequency calculation unit 22B is similar to that in FIG. 17, and thus, detailed description thereof will be omitted here.

### Wavelength-to-Light Intensity Calculation Unit

The wavelength-to-light intensity calculation unit 28A is configured to calculate the wavelength-to-light intensity spec(λ), that is, a wavelength spectrum, indicating the light intensity of the wavelength swept light Lx for individual wavelengths, on the basis of the predicted wavelength λₚ(t) from the predicted wavelength calculation unit 25 and the light intensity pₚ(t) from the relative frequency calculation unit 22B. In the wavelength-to-light intensity calculation unit 28A, the wavelength-to-light intensity spec(λ) may be output from the signal processing apparatus 20, in accordance with a request from a user.

### Effect of Tenth Embodiment

As described above, in the present embodiment, the signal processing apparatus 20 calculates the wavelength-to-light intensity spec(λ) indicating the light intensity of the wavelength swept light Lx for the predicted wavelength λₚ(t), on the basis of the predicted wavelength λₚ(t) obtained as in FIG. 8 and the light intensity pₚ(t) of the wavelength swept light Lx calculated by the relative frequency calculation unit 22B, and measures the swept wavelength width Δλ of the wavelength swept light Lx, on the basis of the wavelength-to-light intensity spec(λ).

Consequently, it is possible to measure the swept wavelength width Δλ of the wavelength swept light Lx with extremely high precision and accuracy, regardless of a sweeping speed of the wavelength swept light source X. Furthermore, when the wavelength-to-light intensity spec(λ) is output to the outside of the signal processing apparatus 20, it is also possible to obtain a wavelength spectrum for the wavelength swept light Lx of the wavelength swept light source X.

### Expansion of Embodiment

The present invention has been described above with reference to the embodiments, but the present invention is not limited to the above-described embodiments. Various changes understood by a person skilled in the art within the scope of the present invention can be made to the configurations and details of the present invention. Furthermore, the embodiments can be freely combined within a range where no inconsistency occurs.

### REFERENCE SIGNS LIST

100, 101, 102, 103, 104, 105, 106, 107, 108, 109 . . . Wavelength swept light measurement system

10 . . . Photoelectric conversion apparatus

11 . . . Interferometer

12 . . . Balanced photodetector

13 . . . Narrow band wavelength filter

14, 15 . . . Photodetector

C1, C2, C3, C4 . . . Coupler

20 . . . Signal processing apparatus

21, 21A . . . Target extraction unit

22, 22A, 22B . . . Relative frequency calculation unit

23, 23A, 23B . . . Sweep frequency width measurement unit

24 . . . Predicted frequency calculation unit

25 . . . Predicted wavelength calculation unit

26, 26A, 26B . . . Swept wavelength width measurement unit

27, 27A, 27B, 27C . . . Frequency-to-light intensity calculation unit

28, 28A . . . Wavelength-to-light intensity calculation unit

30 . . . A/D converter (ADC)

31 . . . Memory

32 . . . Storage apparatus

41 . . . Negative frequency component deletion unit

42 . . . Argument calculation unit

43 . . . Argument-to-frequency conversion unit

44 . . . Light intensity calculation unit

45 . . . Fourier transform unit

46 . . . Negative frequency component replacement unit

47 . . . Inverse Fourier transform unit

X . . . Wavelength swept light source

Lx . . . Wavelength swept light

Trg, trE(t) . . . Trigger electrical signal

iL . . . Interference light

iE(t) . . . Interference electrical signal

λbL . . . Specific wavelength light

λbE(t) . . . Specific wavelength electrical signal

pE(t) . . . Light intensity electrical signal

tr(t) . . . Trigger signal

i(t), i′(t) . . . Interference signal

it(t) . . . Target interference signal

λb(t) . . . Specific wavelength signal

p(t), pp(t) . . . Light intensity

fr(t) . . . Relative frequency

frt(t) . . . Target relative frequency

fp(t) . . . Predicted frequency

λp(t) . . . Predicted wavelength

spf(f), spf(fr) . . . Frequency-to-light intensity

spec(λ) . . . Wavelength-to-light intensity

Δf . . . Sweep frequency width

Δλ . . . Swept Wavelength width

Tmem . . . Effective period

Taq . . . Sweep interval

Ttrg . . . Trigger time

Tpre . . . Pre-time

Tpos . . . Post-time.

1.-8. (canceled)

9. A wavelength swept light measurement system, comprising:
a photoelectric conversion apparatus including an interferometer configured to cause interference in wavelength swept light output from a wavelength swept light source, the photoelectric conversion apparatus being configured to convert the interfered wavelength swept light by photoelectric conversion; and
a signal processing apparatus configured to:
calculate, in chronological order, a plurality of relative frequencies indicating frequencies relative to a plurality of interference signals obtained in the photoelectric conversion; and
determine a difference between a maximum value of the plurality of relative frequencies and a minimum value of the plurality of relative frequencies, as a sweep frequency width of the wavelength swept light.

10. The wavelength swept light measurement system according to claim 9, wherein the signal processing apparatus is further configured to:
extract, from the plurality of interference signals, a plurality of target interference signals corresponding to a sweep interval in which the wavelength swept light is swept from a maximum frequency to a minimum frequency; and
calculate, as the plurality of relative frequencies, differences between a frequency of the target interference signal at a reference time, and frequencies of the plurality of target interference signals at a plurality of times.

11. The wavelength swept light measurement system according to claim 9, wherein the signal processing apparatus is further configured to:
calculate, as the plurality of relative frequencies, differences between a frequency including a frequency of the interference signal at a reference time and frequencies of the interference signal at a plurality of times; and
extract, from the plurality of relative frequencies, a plurality of target relative frequencies corresponding to a sweep interval in which the wavelength swept light is swept from a maximum frequency to a minimum frequency.

12. The wavelength swept light measurement system according to claim 9, wherein the signal processing apparatus is further configured to:
calculate, as the plurality of relative frequencies, differences between a reference frequency including a frequency of the interference signal at a reference time and frequencies of the plurality of interference signals at a plurality of times;
determine time differential values of the plurality of relative frequencies at the plurality of times; and
measure a difference between the plurality of relative frequencies at a time when the time differential values are zero as the sweep frequency width of the wavelength swept light.

13. A wavelength swept light measurement system, comprising:
a photoelectric conversion apparatus including an interferometer configured to cause interference in wavelength swept light output from a wavelength swept light source, the photoelectric conversion apparatus being configured to convert, by photoelectric conversion, the interfered wavelength swept light and specific wavelength light detected by a narrow band wavelength filter from the wavelength swept light; and
a signal processing apparatus configured to:
calculate, in chronological order, a plurality of relative frequencies indicating frequencies relative to a plurality of interference signals obtained in the photoelectric conversion;
calculate a plurality of predicted frequencies indicating absolute frequencies for the plurality of relative frequencies, by referring to a detection timing of the specific wavelength light obtained by the photoelectric conversion of the specific wavelength light; and
calculate a difference between a maximum value of a plurality of predicted wavelengths corresponding to the plurality of predicted frequencies and a minimum value of the plurality of predicted wavelengths, as a swept wavelength width of the wavelength swept light.

14. The wavelength swept light measurement system according to claim 13, wherein the signal processing apparatus is further configured to:
calculate the plurality of predicted frequencies of the plurality of relative frequencies at a plurality of times; and
subsequently calculate the plurality of predicted wavelengths of the plurality of predicted frequencies at the plurality of times.

15. The wavelength swept light measurement system according to claim 13, wherein the signal processing apparatus is further configured to:
determine, as the predicted wavelength, two predicted wavelengths corresponding to a maximum values of the plurality of predicted frequencies and a maximum value of the plurality of predicted frequencies; and
measure a difference between the two predicted wavelengths, as a swept wavelength width of the wavelength swept light.

16. The wavelength swept light measurement system according to claim 13, wherein the signal processing apparatus is further configured to:
determine, as the predicted frequency, two predicted frequencies corresponding to a maximum value of the relative frequencies and a maximum value of the relative frequencies; and
measure a difference between two predicted wavelengths corresponding to the two predicted frequencies as the swept wavelength width of the wavelength swept light.
